(19) United States
(12) Patent Application Publication
(10) Pub. No.: US 2023/0123210 A1
(43) Pub. Date: Apr. 20, 2023

(54) SEMICONDUCTOR DEVICE

(71) Applicant: FLOSFIA INC., Kyoto (JP)

(72) Inventors: Takayoshi OSHIMA, Kyoto (JP); Yasushi HIGUCHI, Kyoto (JP)

(21) Appl. No.: 18/074,879

(22) Filed: Dec. 5, 2022

Related U.S. Application Data
(63) Continuation-in-part of application No. PCT/JP2021/021440, filed on Jun. 4, 2021.

(30) Foreign Application Priority Data
Jun. 5, 2020 (JP) 2020-098784

(51) Int. Cl. H01L 29/06; H01L 29/04; H01L 29/47; H01L 29/24; H01L 29/66; H01L 29/872

(52) U.S. Cl. CPC H01L 29/0661; H01L 29/04; H01L 29/24; H01L 29/47; H01L 29/872; H01L 29/66969

(57) ABSTRACT

Provided is a semiconductor device including: a semiconductor layer; a non-conductive layer that is in contact with at least a part of a side surface of the semiconductor layer directly or via another layer; and a Schottky electrode that is disposed on the semiconductor layer and the non-conductive layer, an end portion of the Schottky electrode being located above the non-conductive layer.

### CROSS REFERENCE TO RELATED APPLICATION

This application is a continuation-in-part application of International Patent Application No. PCT/JP2021/021440 (Filed on Jun. 4, 2021), which claims the benefit of priority from Japanese Patent Application No. 2020-098784 (filed on Jun. 5, 2020).

The entire contents of the above applications, which the present application is based on, are incorporated herein by reference.

### 1. FIELD OF THE INVENTION

The present disclosure relates to a semiconductor device.

### 2. DESCRIPTION OF THE RELATED ART

If a voltage in an opposite direction is applied to a rectifier junction (a Schottky junction or a pn junction) of a semiconductor device, electrical breakdown occurs in a case where a certain voltage (voltage resistance) is exceeded. The voltage at which the electrical breakdown occurs differs between inside of the semiconductor and a surface where the pn junction and/or the Schottky junction terminates, and electrical breakdown typically occurs at a junction termination portion of the semiconductor before the electrical breakdown voltage inside the semiconductor is reached. The voltage resistance of the semiconductor device is the electrical breakdown voltage at the junction termination portion, and the maximum value of the voltage in the opposite direction that may be applied to the semiconductor device thus becomes low, which leads to a problem that the semiconductor device has low voltage resistance. Additionally, three is also a problem that the electrical breakdown occurring at the junction termination portion is unstable, which adversely affects properties of the semiconductor device. Therefore, causing the junction termination portion of the semiconductor to be exposed and working the surface into an oblique shape in order to enhance the strength of the junction termination portion against electrical breakdown is known. Performing beveling by performing griding with an edge portion of a semiconductor wafer pressed against a whetstone surface is known. Also, since there is a problem that the process of working a pn junction function into a bevel structure is technically difficult and the yield thus becomes poor, limiting a location where the bevel structure is provided is known. Also, forming a bevel structure by forming a groove through sandblasting or the like and then jetting an etching solution containing a hydrofluoric acid and a nitric acid into the groove is known. However, in a case where the method of providing a bevel structure by removing a part of semiconductor like grinding is used, there is a problem that the process becomes complicated. Also, performing etching using acids to form a bevel structure also has problems, such as a problem that the surface is roughened. Additionally, it is difficult to create a bevel structure with a desired structure and angle by these methods.

Note that nitride semiconductors containing, for example, silicon carbide, gallium nitride, indium nitride (gallium indium), aluminum nitride (gallium aluminum), and mixed crystals thereof are known as semiconductors and have been used as various semiconductor devices such as blue LEDs and power semiconductors. In recent years, gallium oxide (Ga₂O₃) has attracted attention as a new semiconductor.

As a next generation switching element capable of realizing high voltage resistance, a low loss, and high heat resistance, a semiconductor device using gallium oxide (Ga₂O₃) with a large band gap has attracted attention, and applications thereof to a semiconductor device for power such as an inverter have been expected. Also, a wide range of use thereof as light emitting/receiving devices such as LEDs and sensors has also been expected due to its wide band gap. Particularly, α-Ga₂O₃ or the like having a corundum structure among various kinds of gallium oxide is able to perform band gap control by containing each of indium and aluminum or a combination thereof as mixed crystals and constitutes a very attractive family of materials as an InAlGaO-based semiconductor. Here, InAlGaO-based semiconductors indicate In_{X}Al_{Y}Ga_{Z}O₃ (0 ≤ X ≤ 2, 0 ≤ Y ≤ 2, 0 ≤ Z ≤ 2, X + Y + Z = 1.5 to 2.5) and may be regarded as a family of materials including gallium oxide.

Also, an avalanche photodiode having a single crystal of gallium oxide (Ga₂O₃) is known. There is an example that is the avalanche photodiode including a multilayer structure of the single crystal of Ga₂O₃ and a dielectric layer, a side surface of the multilayer structure has a mesa shape inclined in a reverse tapered shape. However, a method of obtaining such a mesa shape has not been disclosed.

On the other hand, since the most stable phase of gallium oxide (Ga₂O₃) has a β-gallia structure, it is difficult to form a crystalline film with a corundum structure which is a metastable phase unless a special film formation method is used. Also, there have still been a lot of problems not only in the crystalline film with the corundum structure but also in an improvement in film formation rate and crystal quality, suppression of cracking and abnormal growth, twin suppression, cracking of a substrate due to warpage, and the like.

Although a semiconductor device made of a semiconductor material as described above and having a bevel structure has been examined, there are problems such as a difficulty in forming the bevel structure by partial removal of a semiconductor through grinding or the like, a complicated process, and the like, it is difficult to obtain a desired angle and shape of the bevel structure, and a level in which the semiconductor device is advantageously applicable to industrial use has not been achieved.

### SUMMARY OF THE INVENTION

According to an example of the present disclosure, there is provided a semiconductor device including: a semiconductor layer; a non-conductive layer that is in contact with at least a part of a side surface of the semiconductor layer directly or via another layer; and a Schottky electrode that is disposed on the semiconductor layer and the non-conductive layer, an end portion of the Schottky electrode being located above the non-conductive layer.

Thus, in a semiconductor device of the present disclosure, concentration of an electric field at a junction end portion between a semiconductor and a Schottky electrode is curbed

### BRIEF DESCRIPTION OF THE DRAWINGS

FIG. 1 is a schematic view illustrating a part of an aspect of a mask disposed on a surface of a base that is suitably used in an embodiment of the present disclosure.

FIG. 2 is a schematic view illustrating a part of an aspect of the mask disposed on the surface of the base that is suitably used in an embodiment of the present disclosure.

FIG. 3 is a partial sectional view of the base and the mask schematically illustrating a method of forming the mask as illustrated in FIG. 1 and/or FIG. 2. FIG. 3a is a partial sectional view of the base with a mask layer formed on a first surface thereof. FIG. 3b is a partial sectional view of the base in which an opening portion with an inclined surface is formed in the mask layer through etching and of the mask and illustrates, for example, a section at the part IIIb-IIIb in FIG. 1. FIG. 3c is a partial sectional view of a base in which a thinner second mask is formed on a first surface of the base inside an opening portion of a mask layer (first mask) and of the masks according to another embodiment.

FIG. 4 is a diagram schematically illustrating a section of an opening portion of a mask in a case where a protective film is disposed on the mask according to one embodiment of the present disclosure.

FIG. 5 is a diagram for explaining a halide vapor phase epitaxy (HVPE) device used as one embodiment of the present disclosure.

FIG. 6 is a sectional view schematically illustrating a multilayer structure that has been caused to grow on the first surface of the base and the inclined surface of the mask at the opening portion of the mask illustrated in FIG. 3 according to one embodiment.

FIG. 7 is a sectional view schematically illustrating a semiconductor film that has been caused to grow on the protective film illustrated in FIG. 4 according to one embodiment.

FIG. 8 is a diagram for explaining a mist CVD device used in an embodiment of the present disclosure.

FIG. 9 is a photograph showing a semiconductor film obtained in an example of the present disclosure and having an inclined surface at an end portion.

FIG. 10 illustrates a diagram in which an electrode is formed on a first surface of a semiconductor film and a first surface of a mask at the same height according to one embodiment of the present disclosure.

FIG. 11 illustrates a diagram in which an electrode is formed on a first surface of a semiconductor film and a first surface of a mask at a lower position than the first surface of the semiconductor film according to one embodiment of the present disclosure.

FIG. 12 illustrates a diagram in which an electrode is formed on a first surface of a semiconductor film and a first surface of a mask at a higher position than the first surface of the semiconductor film according to one embodiment of the present disclosure.

FIG. 13 illustrates an example of a base used on one embodiment of the present disclosure.

FIG. 14 illustrates an example of a base used on one embodiment of the present disclosure.

FIG. 15 is a diagram illustrating a method of manufacturing a semiconductor device using the base illustrated in FIG. 14 according to one embodiment of the present disclosure.

FIG. 16 illustrates a sectional view of a semiconductor device according to one embodiment of the present disclosure.

FIG. 17 illustrates a sectional view of a semiconductor device according to one embodiment of the present disclosure.

FIG. 18 illustrates a sectional view of a semiconductor device according to one embodiment of the present disclosure.

FIG. 19 illustrates a sectional view of a semiconductor device according to one embodiment of the present disclosure.

FIG. 20 illustrates a sectional view of a semiconductor device according to one embodiment of the present disclosure.

FIG. 21 illustrates, as a diagrammatic view, distribution of electric fields of a semiconductor device (a) which is a semiconductor device in a comparative example that does not include an insulating layer and has a termination of a first electrode located on a semiconductor film and semiconductor devices (b) to (d) which are semiconductor devices that are obtained in an embodiment of the present disclosure, include insulating layers, and have terminations of first electrodes located on the insulating elements.

FIG. 22 is a diagram illustrating distribution of electric field intensities at 10 nm below first electrodes of a semiconductor device (e) that includes an insulating layer (with no bevel structure) and a semiconductor device (f) that includes an insulating layer (with a bevel structure), which are obtained in an embodiment of the present disclosure.

FIG. 23 illustrates semiconductor device sectional views of the semiconductor devices (b) to (d) that are obtained in an embodiment of the present disclosure and include non-conductive layers and electrodes, and of the semiconductor device in Comparative Example (a) that does not include a non-conductive layer.

FIG. 24 is a diagram schematically illustrating a suitable example of a power supply system.

FIG. 25 is a diagram schematically illustrating a suitable example of a system device.

FIG. 26 is a diagram schematically illustrating a suitable example of a power supply circuit diagram of a power supply device.

### DETAILED DESCRIPTION

The inventors of the present disclosure find out that concentration of an electric field at an end portion of a Schottky electrode may be effectively curbed if a semiconductor layer, a non-conductive layer with which at least a part of a side surface of the semiconductor layer is in contact directly or via another layer, and a Schottky electrode that is disposed on the semiconductor layer and the non-conductive layer are included, and an end portion of the Schottky electrode is disposed to be located above the non-conductive layer.

Embodiments of the present disclosure will be described below with reference to the accompanying drawings. In the following description, the same parts and components are designated by the same reference numerals. The present embodiment includes, for example, the following disclosures.

### Structure 1

A semiconductor device including: a semiconductor layer; a non-conductive layer that is in contact with at least a part of a side surface of the semiconductor layer directly or via another layer; and a Schottky electrode that is disposed on the semiconductor layer and the non-conductive layer, an end portion of the Schottky electrode being located above the non-conductive layer.

### Structure 2

The semiconductor device according to [Structure 1], wherein the non-conductive layer includes a first surface on a side of the Schottky electrode, a second surface that is located on a side opposite to the first surface, and a side surface that is located between the first surface and the second surface, the semiconductor layer includes a first surface on the side of the Schottky electrode, a second surface that is located on the side opposite to the first surface, and the side surface that is located between the first surface and the second surface, and the second surface of the semiconductor layer and the second surface of the non-conductive layer are in the same plane.

### Structure 3

The semiconductor device according to [Structure 1], wherein the non-conductive layer includes a first surface on a side of the Schottky electrode, a second surface that is located on a side opposite to the first surface, and a side surface that is located between the first surface and the second surface, the semiconductor layer includes a first surface on the side of the Schottky electrode, a second surface that is located on the side opposite to the first surface, and the side surface that is located between the first surface and the second surface, and the second surface of the non-conductive layer is located at a position closer to the Schottky electrode than the second surface of the semiconductor layer.

### Structure 4

The semiconductor device according to any one of [Structure 1] to [Structure 3], wherein the semiconductor layer contains at least gallium.

### Structure 5

The semiconductor device according to any one of [Structure 1] to [Structure 4], wherein the semiconductor layer contains a crystalline metal oxide as a major component.

### Structure 6

The semiconductor device according to any one of [Structure 1] to [Structure 5], wherein the semiconductor layer contains a mixed crystal of crystalline gallium oxide or gallium oxide.

### Structure 7

The semiconductor device according to any one of [Structure 1] to [Structure 6], wherein the semiconductor layer has a corundum structure.

### Structure 8

The semiconductor device according to any one of [Structure 1] to [Structure 7], wherein the semiconductor layer includes a first surface on a side of the Schottky electrode and a second surface that is located on a side opposite to the first surface, the non-conductive layer includes a first surface on the side of the Schottky electrode and a second surface that is located on the side opposite to the first surface, and the first surface of the semiconductor layer and the first surface of the non-conductive layer are in the same plane.

### Structure 9

The semiconductor device according to any one of [Structure 1] to [Structure 7], wherein the semiconductor layer includes a first surface on a side of the Schottky electrode and a second surface that is located on a side opposite to the first surface, the non-conductive layer includes a first surface on the side of the Schottky electrode and a second surface that is located on the side opposite to the first surface, and the first surface of the semiconductor layer is located at a higher position than the first surface of the non-conductive layer.

### Structure 10

The semiconductor device according to any one of [Structure 1] to [Structure 7], wherein the semiconductor layer includes a first surface on a side of the Schottky electrode and a second surface that is located on a side opposite to the first surface, the non-conductive layer includes a first surface on the side of the Schottky electrode and a second surface that is located on the side opposite to the first surface, and the first surface of the non-conductive layer is located at a higher position than the first surface of the semiconductor layer.

### Structure 11

The semiconductor device according to any one of [Structure 1] to [Structure 10], wherein the side surface of the semiconductor layer includes an inclined surface.

### Structure 12

The semiconductor device according to [Structure 11], wherein the semiconductor layer includes a first surface on a side of the Schottky electrode and a second surface that is located on a side opposite to the first surface and includes the side surface that is located between the first surface and the second surface, and the inclined surface of the semiconductor layer is an inclined surface with a film thickness increasing from the first surface toward the second surface.

### Structure 13

The semiconductor device according to [Structure 11] or [Structure 12], wherein the semiconductor layer includes a first surface on a side of the Schottky electrode and a second surface that is located on a side opposite to the first surface and includes the side surface that is located between the first surface and the second surface, and an angle formed by the first surface of the semiconductor layer and the inclined surface of the semiconductor layer is equal to or greater than 20 ° and equal to or less than 70 °.

### Structure 14

The semiconductor device according to any one of [Structure 11] to [Structure 13], wherein the non-conductive layer includes a first inclined surface, the side surface of the semiconductor layer includes the inclined surface as a second inclined surface inclined in a direction opposite to a direction of the first inclined surface, and the first inclined surface of the non-conductive layer and the second inclined surface of the semiconductor layer are engaged.

### Structure 15

The semiconductor device according to any one of [Structure 1] to [Structure 14], wherein at least a part of the side surface of the semiconductor layer is in close contact with the non-conductive layer.

### Structure 16

The semiconductor device according to any one of [Structure 1] to [Structure 14], wherein at least a part of the side surface of the semiconductor layer is in close contact with the non-conductive layer via a protective film.

### Structure 17

The semiconductor device according to any one of [Structure 1] to [Structure 16], wherein the non-conductive layer is an insulating layer.

### Structure 18

The semiconductor device according to [Structure 17], wherein the insulating layer is made of at least one selected from silicon dioxide (SiO₂) and silicon nitride (Si₃N₄).

### Structure 19

A semiconductor system including at least: a semiconductor device, wherein the semiconductor device is the semiconductor device according to any one of [Structure 1] to [Structure 18].

Although embodiments of the present disclosure will be described below using the drawings, the present disclosure is not limited thereto and may include combinations of elements in the exemplified embodiments and other elements. As one embodiment of the present disclosure, FIG. 20 illustrates a sectional view of a semiconductor device. A semiconductor device 500 includes a semiconductor layer (also referred to as a semiconductor film) 64 and a non-conductive layer 62, with which at least a part of a side surface 64c of the semiconductor layer 64 is in contact, which has a higher insulating property than the semiconductor layer 64. The semiconductor device 500 further includes a first surface 64a of the semiconductor layer 64 on the side of a Schottky electrode 65 and the Schottky electrode 65 that is disposed on a first surface 62a of the non-conductive layer 62 with a higher insulating property than the semiconductor layer 64. An end portion 65c (also referred to as a termination portion) of the Schottky electrode 65 is located on the non-conductive layer 62 with a higher insulating property than the semiconductor layer 64. With the structure as described above, concentration of an electric field at the termination portion of the Schottky electrode may be effectively curbed. The non-conductive layer 62 includes the first surface 62a on the side of the Schottky electrode 65, a second surface 62b that is located on the side opposite to the first surface 62a, and a side surface 62c that is located between the first surface 62a and the second surface 62b, and the semiconductor layer 64 includes the first surface 64a, a second surface 64b that is located on the side opposite to the first surface 64a, and a side surface 64c that is located between the first surface 64a and the second surface 64b. Note that the first surface 64a of the semiconductor layer 64 and the first surface 62a of the non-conductive layer 62 are in the same plane and a structure in which the Schottky electrode 65 may be disposed on the flat surface, concentration of an electric field at the termination portion of the Schottky electrode is curbed, and this leads to a further decrease in thickness of the semiconductor device is thus obtained. Also, according to the present embodiment, the second surface 62b of the non-conductive layer is located at a position closer to the Schottky electrode than the second surface 64b of the semiconductor layer, and a semiconductor device with more excellent voltage resistance may thus be obtained. In the present embodiment, the semiconductor layer 64 is an n- type semiconductor layer, and the semiconductor device 500 further includes an n+ type semiconductor layer (a crystalline layer) 61 that is disposed to be in contact with the second surface 64b of the n- type semiconductor layer 64, and includes an ohmic electrode 66 that is disposed to be in contact with the n+ type semiconductor layer 61. The semiconductor device in the embodiment of the present disclosure is a vertical Schottky barrier diode (SBD).

The semiconductor layer may contain, as a major component, a nitride semiconductor of gallium nitride containing, for example, silicon carbide, gallium nitride, indium nitride, aluminum nitride, and mixed crystals thereof or may contain a crystalline metal oxide as a major component. In the present embodiment, the semiconductor layer preferably contains at least gallium. Also, in the present embodiment, the semiconductor layer preferably contains a crystalline metal oxide as a major component and more preferably contains a mixed crystal of crystalline gallium oxide or gallium oxide. Note that the “major component” means that in a case where the semiconductor layer contains α-Ga₂O₃ as a major component, for example, it is only necessary for α-Ga₂O₃ to be contained at a proportion of equal to or greater than 0.5 in terms of an atomic ratio of gallium in metal elements in the semiconductor layer. In the present disclosure, the atomic ratio of gallium in the metal elements in the semiconductor layer is preferably equal to or greater than 0.7 and is more preferably equal to or greater than 0.8.

The non-conductive layer is made of a material with a higher electrical resistivity than a high-resistant layer and is typically a semi-insulating layer or an insulating layer, and in the embodiment of the present disclosure, the non-conductive layer is preferably an insulating layer. Examples of the semi-insulating layer include polysilicon (polycrystalline silicon), amorphous silicon, diamond-like carbon (DLC), and the like. Also, examples of the material of the insulating layer include oxide, nitride, carbide, and the like such as silicon dioxide (SiO₂), silicon nitride (Si₃N₄), silicon (Si), germanium (Ge), titanium (Ti), zirconium (Zr), Hf (Hafnium), Ta (tantalum), and tin (Sn). Curbing of concentration of an electric field may be more effectively expressed by combining the preferable insulating layer as described above with a bevel structure, which will be described later.

Also, FIG. 16 illustrates a sectional view of a semiconductor device according to another embodiment of the present disclosure. A semiconductor device 100 includes a semiconductor film 64 including a first surface 64a, a second surface 64b that is located on the side opposite to the first surface 64a, a side surface that is located between the first surface 64a and the second surface 64b, an inclined surface 64c that is provided in at least a part of the side surface, a first region 64f at a position that is adjacent to the inclined surface (a second inclined surface) 64c, and a second region 64g at a position further from the inclined surface 64c than the first region 64f in a plan view. The first region 64f is at a position closer to the side surface of the semiconductor film 64, and the second region 64g is at a position including a center portion of the semiconductor film 64. In the present embodiment, the first region 64f near the end portion of the semiconductor film where an electric field is likely to concentrate includes crystals which have grown in the lateral direction, and the dislocation density in the first region 64f is lower than the dislocation density in the second region 64g, which leads to an improvement in semiconductor properties. The semiconductor layer 64 and a non-conductive layer 62 with which at least a part of the side surface of the semiconductor layer 64 is in contact are included. The non-conductive layer 62 is preferably an insulating layer, the side surface of the non-conductive layer 62 includes a first inclined surface 62c, the side surface of the semiconductor layer 64 includes a second inclined surface 64c that is inclined in the direction opposite to the direction of the first inclined surface 62c, and the first inclined surface 62c of the non-conductive layer 62 and the second inclined surface 64c of the semiconductor layer 64 are engaged. In the present embodiment, a positive bevel structure is included at an end portion of the semiconductor layer 100, and the first inclined surface 62c of the non-conductive layer 62 and the second inclined surface 64c of the semiconductor layer 64 are in close contact with each other. Furthermore, the semiconductor device 100 in the present embodiment includes a rectifier junction interface 90, and includes a first electrode 65 (a Schottky electrode here) joined to the semiconductor film 64 at the rectifier junction interface 90. The first electrode 65 is disposed on the first surface 64a of the semiconductor layer 64 and the first surface 62a of the non-conductive layer 62. An end portion 65c (also referred to as a termination portion) of the Schottky electrode 65 is located on the non-conductive layer 62. An angle formed by the first surface 64a of the semiconductor layer 64 and the inclined surface 64c of the semiconductor layer 64 is less than 90°. In other words, the inclined surface 64c of the semiconductor layer 64 is an inclined surface with a film thickness increasing in a direction from the first surface 64a to the second surface 64b of the semiconductor layer. Note that an inclination angle 64e formed between the first surface 64a and the inclined surface 64c of the semiconductor layer 64 preferably falls within a range of 10° < the inclination angle 64e < 90° and the inclination angle 64e is more preferably equal to or less than 70° and is most preferably equal to or greater than 20° and equal to or less than 70°. With the structure as described above, a leaking current may be curbed in the positive bevel structure, and concentration of an electric field at the termination portion of the Schottky electrode may be effectively curbed. Also, in the present embodiment, the second surface 64b of the semiconductor layer 64 and the second surface 62b of the non-conductive layer 62 with a higher insulating property than the semiconductor layer 64 are in the same plane. Additionally, the first surface 64a of the semiconductor layer 64 and the first surface 62a of the non-conductive layer 62 are in the same plane, and a structure in which the Schottky electrode 65 may be disposed on the flat surface, concentration of an electric field at the termination portion of the Schottky electrode is curbed, and this leads to a decrease in thickness of the semiconductor device is thus obtained. In the present embodiment, the semiconductor layer 64 is, for example, an n- type semiconductor layer, and the semiconductor device 100 further includes an n+ type semiconductor layer 61 that is disposed to be in contact with the second surface 64b of the n- type semiconductor layer 64 and a second electrode 66 (an ohmic electrode here) that is disposed to be in contact with the n+ type semiconductor layer 61. The semiconductor device in the embodiment of the present disclosure is a vertical Schottky barrier diode (SBD). Note that the “rectifier junction interface” is not particularly limited as long as it is a junction interface having a rectifying effect. In the embodiment of the present disclosure, the rectifier junction is preferably a Schottky junction or a pn junction.

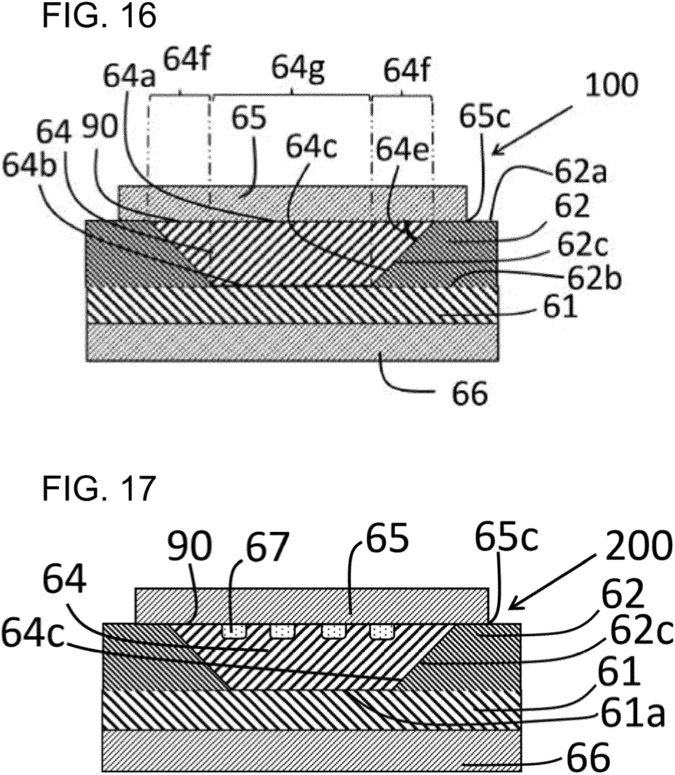

In addition, FIG. 17 illustrates a sectional view of a semiconductor device according to another embodiment of the present disclosure. A semiconductor device 200 is different from the semiconductor device 100 in FIG. 16 in that the semiconductor device 200 includes a plurality of p type semiconductor portions 67 located between a Schottky electrode 65 and an n- type semiconductor layer 64. With such a configuration, concentration of an electric field at a junction (Schottky junction) interface 90 between the Schottky electrode 65 and the n- type semiconductor layer 64 may be further curbed. Note that the p type semiconductor portions 67 may be formed by providing grooves in the n- type semiconductor layer 64 and causing the p type semiconductor portions 67 to grow therein or may be provided through ion implantation, for example. The semiconductor device in the embodiment of the present disclosure is a vertical junction barrier Schottky diode (JBS).

Additionally, FIG. 18 illustrates a sectional view of a semiconductor device according to another embodiment of the present disclosure. A semiconductor device 300 in the present embodiment is different from the semiconductor device 100 in FIG. 16 in that a protective film 63 of a different material from that of a non-conductive layer 62 is disposed on the non-conductive layer 62. The protective film 63 also has a higher insulating property than the semiconductor layer 64 and is preferably a non-conductive layer, and in a case where the non-conductive layer 62 contains silicon (Si), for example, the protective film 63 is preferably a protective film 63 of a material that does not contain Si (silicon-free). Examples of the material of the protective film 63 include oxide, nitride, carbide, and the like such as silicon nitride (Si₃N₄), germanium (Ge), titanium (Ti), zirconium (Zr), Hf (Hafnium), Ta (tantalum), and tin (Sn). According to one embodiment of the present disclosure, the non-conductive layer 62 may be used as a mask when a positive bevel structure is formed at an end portion of an epitaxially grown semiconductor film and/or a multilayer structure including two or more semiconductor films, and a general-purpose mask material often contains Si. In this case, Si in the mask material is prevented from being taken into the semiconductor film, and the semiconductor film and/or the multilayer structure including two or more semiconductor films including a positive bevel structure may be obtained, by disposing the protective film 63 that does not contain Si on the mask. Although details will be described later, the protective film is a thin film disposed on the mask after the inclined surface of the mask is formed, and the semiconductor film and/or the multilayer structure including two or more semiconductor films is formed on the protective film. Therefore, the protective film 63 preferably covers at least the inclined surface 62c of the non-conductive layer 62, and the first inclined surface 62c of the non-conductive layer 62 is preferably in close contact with the inclined surface of the end portion of the semiconductor layer and/or the inclined surface of the end portion of the multilayer structure via the protective film 63.

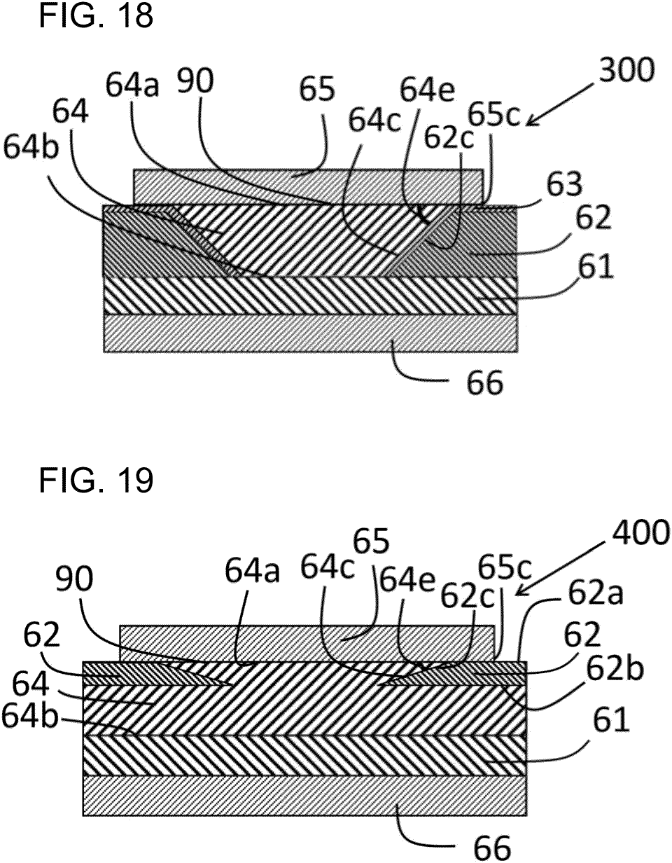

Furthermore, FIG. 19 illustrates a sectional view of a semiconductor device according to another embodiment of the present disclosure. A semiconductor device 400 in the present embodiment is different from the semiconductor device 100 in FIG. 16 in that the second surface 62b of the non-conductive layer is located at a position closer to the Schottky electrode than the second surface 64b of the semiconductor layer. In the embodiment of the present disclosure, a semiconductor layer 64 is caused to epitaxially grow, a mask having an inclined surface 62c is disposed on the semiconductor layer 64, and the semiconductor layer 64 with a positive bevel structure having an inclined surface 64c in at least a part of the end portion of the semiconductor layer 64 may be thereby formed. The mask may be used as the non-conductive layer 62 of the semiconductor device for disposing the termination portion of the Schottky electrode. In the present embodiment, at least the inclined surface 62c and the second surface 62b of the non-conductive layer 62 are buried in the semiconductor layer 64. In other words, in the present embodiment, the second surface 62b of the non-conductive layer is located at a position closer to the Schottky electrode than the second surface 64b of the semiconductor layer. The structure as described above not only enables a semiconductor device with more excellent voltage resistance to be obtained but also enables concentration of an electric field at the termination portion of the Schottky electrode to be more effectively curbed while the thickness required for the non-conductive layer 62 is reduced.

In the embodiment of the manufacturing method of present disclosure, a film formation method of the semiconductor layer (hereinafter, also referred to as the semiconductor film) is not particularly limited as long as the film formation method is able to cause the semiconductor layer to epitaxially grow. Examples of the film formation method of the semiconductor layer include at least one method selected from a spray method, mist CVD, HVPE, MBE, MOCVD, and a sputtering process.

An example of a method of forming the semiconductor layer using HVPE shown in FIG. 5 will be described. For example, an HVPE system is able to cause the semiconductor film to form by gasifying a metal source containing metal to obtain metal-containing source gas and supplying the metal-containing source gas and oxygen-containing source gas to the space above a base inside a reaction chamber, the base being arranged the mask having the inclined surface. When forming the semiconductor film, the HVPE system is also able to cause the semiconductor film to form by supplying the metal-containing source gas, oxygen-containing source gas and reactive gas to the space above the base being arranged the mask having the inclined surface. For example, a HVPE apparatus 50 includes a reaction chamber 51, a heater 52a to heat a metal source 57, and a heater 52b to heat the base held by the base holder 56. The HVPE apparatus 50 further includes a supply tube 55b of oxygen-containing raw material gas, a supply gas tube 54b of reactive gas, and a substrate holder 56, on which the substrate is placed, in the reaction chamber 51. Furthermore, a supply tube 53b of metal-containing raw-material gas was arranged in the supply gas tube 54b of reactive gas to have a double-tube structure. The supply tube 55b of oxygen-containing raw material gas is connected to the supply device 55a of oxygen-containing raw material gas to form a flow path of the oxygen-containing raw material gas such that the oxygen-containing raw-material gas is supplied from the supply device 55a of oxygen-containing raw material gas via the supply tube 55b of oxygen-containing raw material gas to the substrate held by the substrate holder 56. The supply gas tube 54b of reactive gas is connected to a supply device 54a of reactive gas to form a flow path of reactive gas such that reactive gas is supplied from the supply device 54a via supply gas tube 54b to the substrate held by the substrate holder 56. The supply tube 53b of metal-containing raw-material gas is connected to the supply device 53a of halogen-containing raw-material gas such that the halogen-containing raw-material gas is supplied to the metal source to form metal-containing raw-material gas. The supply tube 53b of metal-containing raw-material gas is connected to the supply device 53a of halogen-containing raw-material gas such that the halogen-containing raw-material gas is supplied to the metal source to form metal-containing raw-material gas. The metal-containing gas is then supplied onto the substrate held by the substrate holder 56. The reaction chamber 51 further includes a gas discharge portion 59 to discharge used gas and a protection sheet 58 arranged on an inner surface of the reaction chamber 51 to prevent reacted material from depositing on.

### Metal Source

The metal source is not limited to a particular metal source as long as the metal source contains metal and can be gasified, and may be elemental metal or a metal compound. Examples of the metal include one or two or more types of metal selected from gallium, aluminum, indium, iron, chromium, vanadium, titanium, rhodium, nickel, cobalt, iridium and so forth. In the present disclosure, the metal is preferably one or two or more types of metal selected from gallium, aluminum, and indium and more preferably gallium, and the metal source is most preferably elemental gallium. Moreover, the metal source may be gas, liquid, or solid; in the present disclosure, when gallium is used as the metal, for example, it is preferable that the metal source is liquid.

A means for the gasification is not limited to a particular means unless it interferes with the object of the present disclosure, and may be a publicly known means. In the present disclosure, it is preferable that the means for the gasification is performed by halogenating the metal source. A halogenating agent that is used in the halogenation is not limited to a particular halogenating agent as long as the halogenating agent can halogenate the metal source, and may be a publicly known halogenating agent. Examples of the halogenating agent include halogens, hydrogen halides or the like. Examples of the halogens include fluorine, chlorine, bromine, iodine or the like. Moreover, examples of the hydrogen halides include hydrogen fluoride, hydrogen chloride, hydrogen bromide, and hydrogen iodide. In the present disclosure, a hydrogen halide is preferably used in the halogenation and hydrogen chloride is more preferably used in the halogenation. In the present disclosure, it is preferable that the gasification is performed by supplying a halogen or hydrogen halide to the metal source as a halogenating agent and making the metal source and the halogen or hydrogen halide react with each other at a temperature equal to or higher than a vaporization temperature of a metal halide to form a metal halide. The halogenation reaction temperature is not limited to a particular temperature; in the present disclosure, when, for example, the metal source is gallium and the halogenating agent is HCl, the halogenation reaction temperature is preferably 900° C. or lower, more preferably 700° C. or lower, and most preferably 400 to 700° C. The metal-containing source gas is not limited to particular metal-containing source gas as long as the metal-containing source gas is gas containing the metal of the metal source. Examples of the metal-containing source gas include a halide (such as fluoride, chloride, bromide, or iodide) of the metal.

In an embodiment of the present disclosure, after a metal source containing metal is gasified to obtain metal-containing source gas, the metal-containing source gas and the oxygen-containing source gas are supplied to the space above a substrate inside the reaction chamber. Moreover, in an embodiment of the present disclosure, reactive gas is supplied to the space above the substrate. Examples of the oxygen-containing source gas include O₂ gas, CO₂ gas, NO gas, NO₂ gas, N₂O gas, H₂O gas, O₃ gas or the like. In the present disclosure, the oxygen-containing source gas is preferably one or two or more types of gas selected from a group consisting of O₂, H₂O, and N₂O and more preferably contains O₂. It is to be noted that the oxygen-containing source gas may contain CO₂ as one of embodiments. The reactive gas is generally reactive gas that is different from metal-containing source gas and oxygen-containing source gas and inert gas is not included therein. The reactive gas is not limited to particular reactive gas and examples thereof include etching gas. The etching gas is not limited to particular etching gas unless it interferes with the object of the present disclosure, and may be publicly known etching gas. In the present disclosure, the reactive gas is preferably halogen gas (for example, fluorine gas, chlorine gas, bromine gas, or iodine gas), hydrogen halide gas (for example, hydrofluoric acid gas, hydrochloric acid gas, hydrobromic gas, and hydrogen iodide gas), hydrogen gas, mixed gas of two or more of these gases, or the like, preferably contains hydrogen halide gas, and most preferably contains hydrogen chloride. It is to be noted that the metal-containing source gas, the oxygen-containing source gas, and the reactive gas may contain carrier gas. Examples of the carrier gas include inert gas such as nitrogen and argon. Moreover, the partial pressure of the metal-containing source gas is not limited to a particular partial pressure; in the present disclosure, the partial pressure of the metal-containing source gas is preferably 0.5 Pa to 1 kPa and more preferably 5 Pa to 0.5 kPa. The partial pressure of the oxygen-containing source gas is not limited to a particular partial pressure; in the present disclosure, the partial pressure of the oxygen-containing source gas is preferably 0.5 to 100 times higher than the partial pressure of the metal-containing source gas and more preferably 1 to 20 times higher than the partial pressure of the metal-containing source gas. The partial pressure of the reactive gas is also not limited to a particular partial pressure; in an embodiment of the present disclosure, the partial pressure of the reactive gas is preferably 0.1 to 5 times higher than the partial pressure of the metal-containing source gas and more preferably 0.2 to 3 times higher than the partial pressure of the metal-containing source gas.

In an embodiment of the present disclosure, it is also preferable to supply dopant-containing gas to the substrate. The dopant-containing gas is not limited to particular dopant-containing gas as long as the dopant-containing gas contains dopant. The dopant is also not limited to particular dopant; in the present disclosure, the dopant preferably contains one or two or more types of elements selected from germanium, silicon, titanium, zirconium, vanadium, niobium, and tin, more preferably contains germanium, silicon, or tin, and most preferably contains germanium. By using the dopant-containing gas as described above, it is possible to easily control the conductivity of a film to be obtained. The dopant-containing gas preferably contains the dopant in the form of a compound (for example, a halide or oxide) and more preferably contains the dopant in the form of a halide. The partial pressure of the dopant-containing gas is not limited to a particular partial pressure; in the present disclosure, the partial pressure of the dopant-containing gas is preferably 1×10⁻⁷ to 0.1 times higher than the partial pressure of the metal-containing source gas and more preferably 2.5×10⁻⁶ to 7.5×10⁻² times higher than the partial pressure of the metal-containing source gas. It is to be noted that, in the present disclosure, it is preferable to supply the dopant-containing gas to the space above the substrate along with the reactive gas.

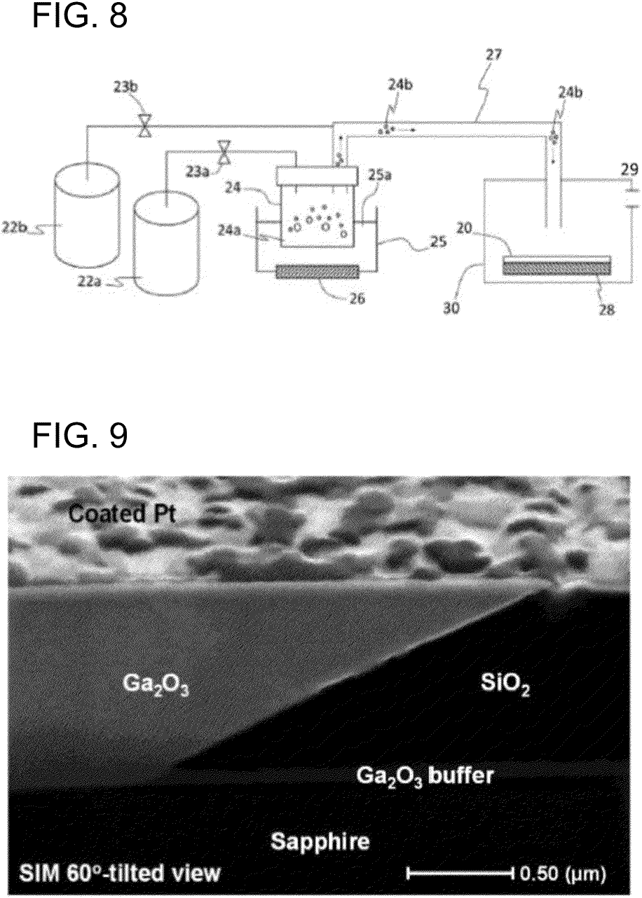

As another example mentioned later, at least a part of the semiconductor film and/or base in the embodiment of the present disclosure may be formed by such a mist CVD device shown in FIG. 8 .

### Base

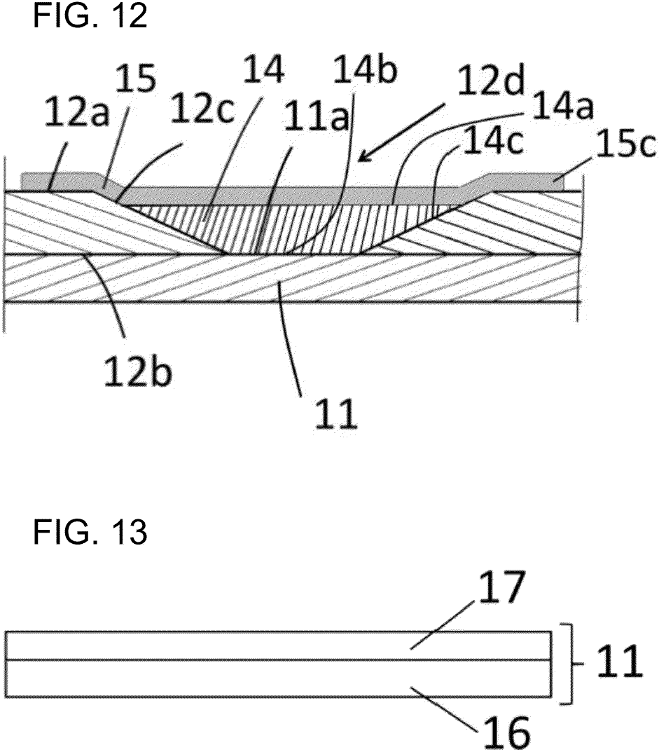

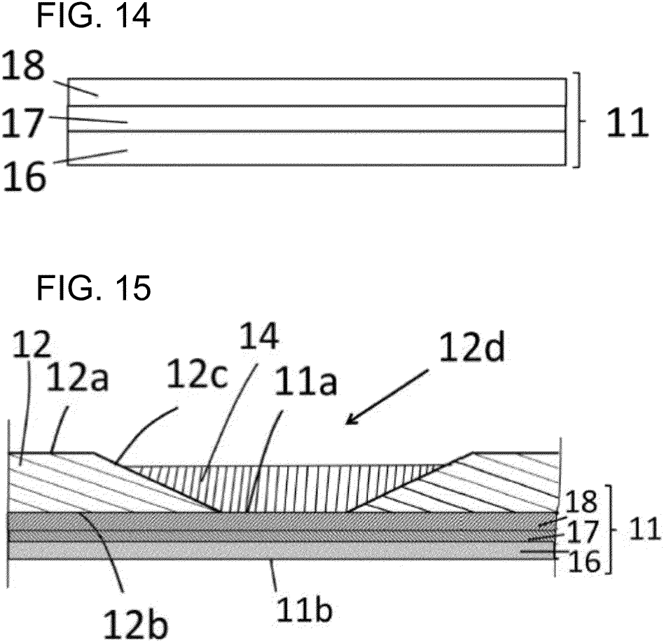

The base is not particularly limited as long as the base is able to support the mask and/or the semiconductor film. The material of the base is not particularly limited unless it interferes with the present disclosure, a known base may be used, and the material of the base may be an organic compound or may be an inorganic compound. The shape of the base may be any shape and is effective for any shape, examples thereof include a plate shape such as a flat plate or a disk, a fiber shape, a rod shape, a columnar shape, a prismatic shape, a tubular shape, a spiral shape, a spherical shape, and a ring shape, and a substrate is preferable in one embodiment of the present disclosure. Also, the base preferably includes a crystalline layer in another embodiment of the present disclosure. The crystalline layer may be a semiconductor layer. As illustrated in FIG. 13, for example, the base 11 may include a substrate 16 and a crystalline layer (including a semiconductor layer) 17 formed on the substrate 16. The thickness of the substrate is not particularly limited in the present disclosure. Also, another layer such as a buffer layer may be laminated on the substrate as the base as will be described later. An element including a semiconductor layer with different electrical conductivity may be used as the base, or the base itself may be a semiconductor layer. As illustrated in FIG. 14, for example, the base 11 may include the substrate 16, the crystalline layer 17 (for example, this may be a semiconductor layer like an n+ type semiconductor layer) that is disposed on the substrate 16, and yet another crystalline layer 18 (for example, this may be a semiconductor layer like an n- type semiconductor layer) that is disposed on the crystalline layer 17. In this case, the semiconductor layer 18 is formed as a part of the base 11, and a mask layer is then disposed on the semiconductor layer 18 that serves as a first surface 11a of the base 11, as illustrated in FIG. 15. Next, it is also possible to remove a part of the mask layer through etching to form an opening portion 12d having an inclined surface 12c, to cause the semiconductor layer 18 that serves as the first surface 11a of the base 11 to be exposed to the inside of the opening portion 12d, and to cause the semiconductor film 14 to continuously grow with the same semiconductor material as that of the semiconductor layer 18. In this manner, a semiconductor device, in which the mask 12 including the inclined surface having at least a part buried in the semiconductor film is disposed, which includes a semiconductor film having, in at least a part of the semiconductor film, a bevel structure engaged with the inclined surface of a mask 12 (non-conductive layer), may be easily obtained by causing the semiconductor film 14 to epitaxially grow using the same material as that of the semiconductor layer 18 which is a part of the base 11. As illustrated in FIG. 19, for example, the semiconductor device 400, in which at least the inclined surface 62c and the second surface 62b of the non-conductive layer 62 are buried in the semiconductor layer 64, which includes the inclined surface 64c engaged with the inclined surface 62c of the non-conductive layer 62, may also be obtained. Also, as in the present embodiment, the layer located on the first surface 11a of the base 11 and the layer located on the second surface 11b on the side opposite to the first surface 11a may be crystalline layers and/or semiconductor layers with mutually different compositions. The opening portion may be formed such that the inclined surface is disposed in at least a part of the side surface of the opening portion 12 of the mask 12 in one embodiment of the present disclosure, or the opening portion of the mask layer may be formed such that an annular inclined surface is disposed over the entire side surface of the opening portion of the mask layer in another embodiment.

### Crystalline Substrate

When the substrate includes a crystalline substrate or is the crystalline substrate, The crystalline substrate is not limited to a particular crystalline substrate as long as the crystalline substrate is a substrate containing a crystalline substance as a major component, and may be a publicly known substrate. The crystalline substrate may be an insulator substrate, a conductive substrate, or a semiconductor substrate. The crystalline substrate may be a monocrystalline substrate or a polycrystalline substrate. Examples of the crystalline substrate include a silicon carbide (SiC) substrate, a gallium nitride (GaN) substrate, a substrate containing a crystal substance having a corundum structure as a major component, a substrate containing a crystal substance having a β-gallia structure as a major component, a substrate having a hexagonal structure, or the like. It is to be noted that the “major component” refers to the crystal substance constituting 50% or more, preferably 70% or more, and more preferably 90% or more of the substrate in terms of composition ratio.

Examples of the substrate containing a corundum-structured crystal as a major component include a sapphire (α-Al₂O₃) substrate and an α-phase gallium oxide (α-Ga₂O₃) substrate. Examples of the substrate containing a β-gallia-structured crystal as a major component include p-phase gallium oxide β-Ga₂O₃) substrate and a substrate containing a mixed crystal of β—Ga₂O₃ and α—Al₂O₃. As a substrate containing the mixed crystal of β—Ga₂O₃ and α—Al₂O₃, the substrate of the mixed crystal in which Al₂O₃ is contained in a range of more than 0% to 60% or less in terms of atomic ratio. Also, examples of the hexagonal-structured substrate include a silicon carbide (SiC) substrate, a zinc oxide (ZnO) substrate, a gallium nitride (GaN) substrate. An example of another crystalline substrate is a silicon (Si) substrate, for example.

In an embodiment of the present disclosure, it is preferable that the crystalline substrate is a sapphire substrate. Examples of the sapphire substrate include a c-plane sapphire substrate, an m-plane sapphire substrate and an a-plane sapphire substrate. The sapphire substrate may include an off-angle. The off-angle of the sapphire substrate is not particularly limited, however, preferably in a range of 0° to 15°. Also, the thickness of the crystalline substrate is not particularly limited, however preferably in a range of 50 µm to 2000 µm, and further preferably in a range of 200 µm to 800 µm.

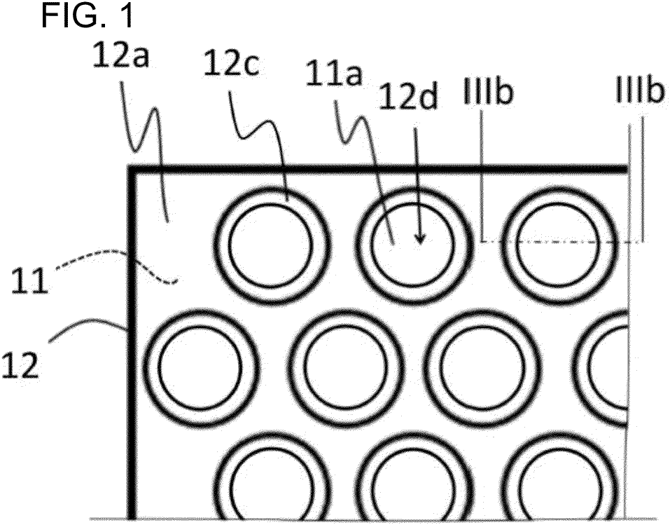

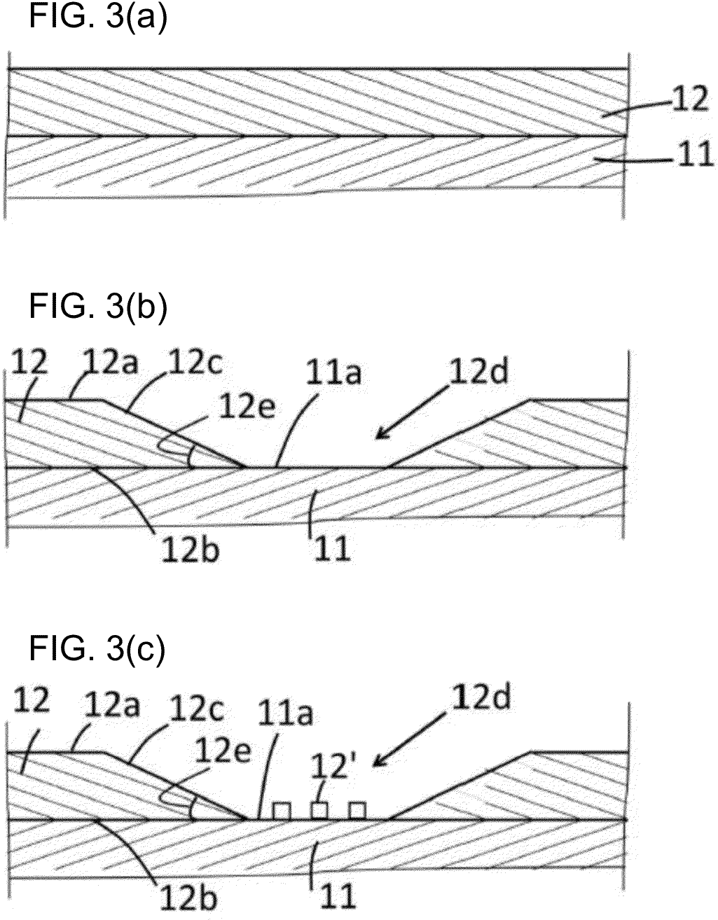

FIG. 1 schematically illustrates a part of an aspect of a mask that is disposed on the surface of the base 11 according to one embodiment of the present disclosure. Specifically, a mask layer is formed as the mask 12 on the first surface 11a of the base 11 as illustrated in (a) of FIG. 3. As the mask material, the mask may be formed of a material with a higher electrical insulating property than the semiconductor film, and for example, the mask material is preferably a semi-insulating material or an insulating material. Examples of the semi-insulating material include polysilicon (polycrystalline silicon), amorphous silicon, diamond-like carbon (DLC), undoped crystalline layers, and crystalline layers containing semi-insulating dopants such as magnesium (Mg), ruthenium (Ru), iron (Fe), beryllium (Be), cesium (Cs), strontium (Sr), and barium (Ba). Also, examples of the insulating material include oxide, nitride, carbide, and the like such as silicon dioxide (SiO₂), silicon nitride (Si₃N₄), silicon (Si), germanium (Ge), titanium (Ti), zirconium (Zr), Hf (Hafnium), Ta (tantalum), and tin (Sn). Note that in the embodiment of the present disclosure, the mask layer is more preferably made of an insulator. The base 11 includes the first surface 11a and the second surface 11b on the side opposite to the first surface 11a. The mask layer 12 (hereinafter, also referred to as a mask and/or a first mask) is formed on the first surface 11a of the base 11, a resist layer is disposed on at least a part of the mask layer 12, for example, the mask layer 12 is etched using etching gas and/or an etching solution, and the annular inclined surface 12c may thus be formed on the side surface of the opening portion 12d of the mask layer as illustrated in (b) of FIG. 3. Although the etching may be dry etching or wet etching in the embodiment of the present disclosure, an isotropic etching is preferably performed since the inclined surface is formed in the mask layer. According to another embodiment of the present disclosure, anisotropic etching and isotropic etching may be combined. For example, the opening may be provided in the mask layer through anisotropic etching, and isotropic etching may be additionally performed to adjust the inclination angle of the inclined surface.

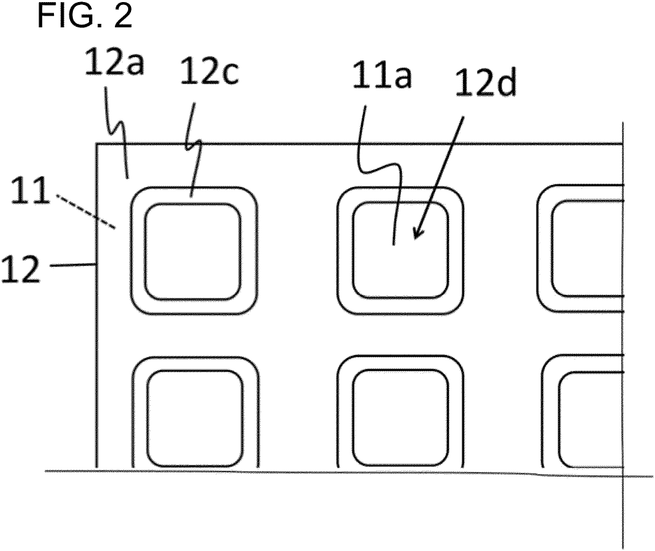

FIG. 3b illustrates a section at the part IIIb-IIIb in FIG. 1, for example. The opening portion 12d of the mask 12 penetrates from a first surface 12a to a second surface 12b of the mask 12 on the opposite side, and the second surface 12b of the mask 12 is located at a position closer to the first surface 11a of the base 11 than the first surface 12a of the mask 12. The thick film formation and working of the mask layer may be easily performed in a short period of time as compared with working such as grinding of the semiconductor film, and it is also easy to obtain a smooth inclined surface of the mask. Since the mask including the inclined surface in the embodiment of the present disclosure is used for forming a bevel structure at the end portion of the semiconductor film and/or the multilayer structure as one purpose, the mask has the same thickness as the thickness of the semiconductor film or has a thickness that is equal to or greater than the thickness of the semiconductor film. Therefore, the thickness of the mask in which the inclined surface is formed is preferably at least equal to or greater than 1 µm and is preferably equal to or greater than 1 µm and equal to or less than 100 µm. Furthermore, according to another embodiment, it is also possible to form a mask layer as the mask 12 on the first surface 11a of the base 11, to forms the opening portion 12d including the inclined surface 12c, and then further to dispose a second mask 12′ with a projecting shape and with a smaller surface area than the size of the opening portion on the first surface 11a of the base 11 inside the opening portion 12d at a height that is equal to or less than half the height of the mask 12 as a first mask as illustrated in FIG. 3c. In this manner, the semiconductor film 14 including the inclined surface at the end portion and including less dislocation may also be obtained by causing epitaxial growth of the semiconductor film 14 including lateral growth from the first surface 11a of the base 11 to the second mask 12′ and further causing epitaxial growth of the semiconductor film 14 including lateral growth on the inclined surface 12c of the first mask 12. Since the inclined surface may be formed into an annular shape at the peripheral end portion of the semiconductor film, the semiconductor device having a bevel structure may be easily manufactured. Note that in the embodiment of the present disclosure, the shape of the opening portion 12d is preferably a shape with no corners in a plan view. As illustrated in FIG. 2, the shape of the opening portion 12d may be a square with rounded corners in a plan view. Note that in the present embodiment, the opening portion 12d of the mask 12 has a circular shape in a plan view and a side surface of the mask 12 inside the opening portion 12d is the inclined surface 12c that is inclined in a direction approaching the center of the opening portion 12d toward the first surface 11a of the base 11 in a plan view. In the sectional view of the opening portion 12d, the inclined surface 12c of the mask 12 has a tapered shape with a thickness decreasing from the first surface of the mask toward the second surface of the mask. The first surface 12a of the mask 12 is parallel with the second surface 12b, and the second surface 12b of the mask 12 has a larger area than the first surface 12a of the mask 12. The semiconductor film 14 including the annular inclined surface at the peripheral end portion may be formed in a circular shape in a plan view, for example, by causing the semiconductor film 14 to grow on the base 11 where the mask 12 including the inclined surface 12c is disposed. According to the manufacturing method in the embodiment of the present disclosure, the semiconductor device 100 as illustrated in FIG. 16, for example, may be easily obtained. The semiconductor device 100 includes the semiconductor film 64 including a flat first surface 64a, a second surface 64b provided with a smaller area than that of the first surface 64a on the side opposite to the first surface 64a, and an inclined surface 64c at the end portion located between the first surface 64a and the second surface 64b. It is also possible to dispose a Schottky electrode as the first electrode 65 on the side of the first surface 64a of the semiconductor film 64 and to dispose the ohmic electrode 66 as a second electrode on the side of the second surface 64b. Also, in the method of manufacturing the semiconductor device according to the embodiment of the present disclosure, it is also possible to dispose a mask on the crystalline layer 61 and to cause a semiconductor layer (for example, an n+ type semiconductor layer) including an inclined surface at an end portion to epitaxially grow. If the semiconductor film 64 (for example, an n- type semiconductor layer) including an inclined surface continuing to the inclined surface of the n+ type semiconductor layer is caused to epitaxially grow on the n+ type semiconductor layer, a Schottky barrier diode (SBD) which is a semiconductor device having a positive bevel structure at the end portion of the multilayer structure may be easily obtained. Also, according to the manufacturing method in the embodiment of the present disclosure, it is also possible to form inclined surfaces at end portions of two layers with different electrical conductivity, for example. Note that the inclination angle 64e formed between the first surface 64a and the inclined surface 64c of the semiconductor film 64 preferably falls within a range of 10° < the inclination angle 64e < 90° and the inclination angle 64e is preferably equal to or less than 70° and is most preferably equal to or greater than 20° and equal to or less than 70°. For example, in the embodiment of the manufacturing method of the present disclosure, it is also possible to obtain a semiconductor device which includes an inclined surface formed to continue from an inclined surface of a first semiconductor film to an inclined surface of a second semiconductor film and has a positive bevel structure at end portions (including peripheral end surfaces) of the plurality of semiconductor layers. Note that the “semiconductor device” having the “positive bevel structure” means a structure in which the sectional area at the end portion of the semiconductor film and/or the multilayer structure including two or more semiconductor films decreases toward a side on which a depletion layer spreads. Also, it means a structure in which the angle formed between the rectifier junction interface and an end surface of a low-impurity-concentration layer is an acute angle. In a case where the semiconductor device is a vertical SBD as in FIG. 16, for example, the rectifier junction interface is a junction (Schottky junction) interface between the Schottky electrode and the n- type semiconductor layer, and the end surface of the low-impurity-concentration layer is an end surface of the n- type semiconductor layer. In this case, a structure in which the sectional area of the semiconductor film that is parallel with the Schottky electrode decreases in a direction from the side of the Schottky electrode toward the side of the ohmic electrode is included. A case where the semiconductor film and/or the multilayer structure of two or more semiconductor films has a shape such as a reverse circular truncated cone is also included.

In addition, the mask 12 may also be used as the insulating layer 62 of the semiconductor device 100 illustrated in FIG. 16. Note that the thickness of the mask 12 may be appropriately set, the mask 12 may be disposed as an insulating layer such that at least a part thereof is buried in the semiconductor film (layer), and the mask 12 may thus be used as a field insulating film of the semiconductor device. Also, according to another embodiment, an inclined surface may be formed in at least a part of the end portion of the semiconductor film by setting the thickness of the mask 12 to be the same as that of the semiconductor film or to be thicker than the thickness of the semiconductor film. In a case where the inclined surface is formed in at least a part of the end portion of the multilayer structure of two or more semiconductor films, the inclined surface may be formed in at least a part of the end portion of the multilayer structure by setting the thickness of the mask 12 to be the same as that of the multilayer structure or to be thicker than the thickness of the multilayer structure. The embodiment of the present disclosure not only enables a bevel structure to be easily formed but also enables the field insulating film to be easily formed. Note that although the inclined surface 64c may be provided in at least a part of the end portion located between the first surface 64a and the second surface 64b, the inclined surface 64c is preferably provided over the entire end portion, that is, over the peripheral end portion of the semiconductor film 64 in the present embodiment. A Schottky barrier diode having a positive bevel structure in which the inclination angle formed between the first surface 64a and the inclined surface 64c is less than 90° may be obtained if the Schottky electrode is disposed on the side of the first surface 64a of the semiconductor film 64. Also, in the present embodiment, the inclination angle 64e formed between the first surface 64a and the inclined surface 64c of the semiconductor film 64 preferably falls within a range of 10° < the inclination angle 64e < 90°, and the inclination angle 64e is more preferably equal to or less than 70° and is most preferably equal to or greater than 20° and equal to or less than 70°.

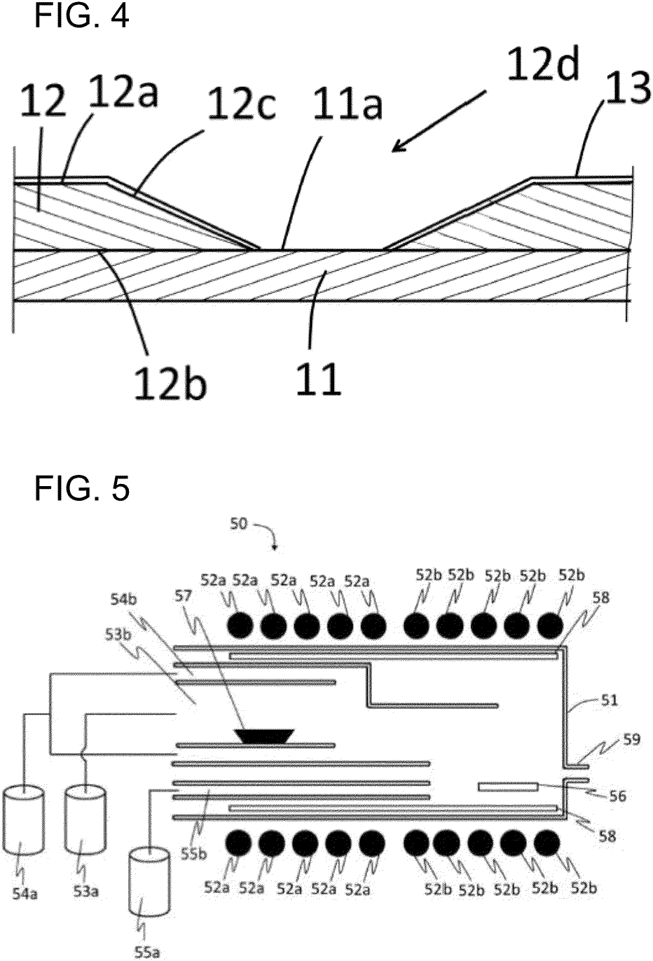

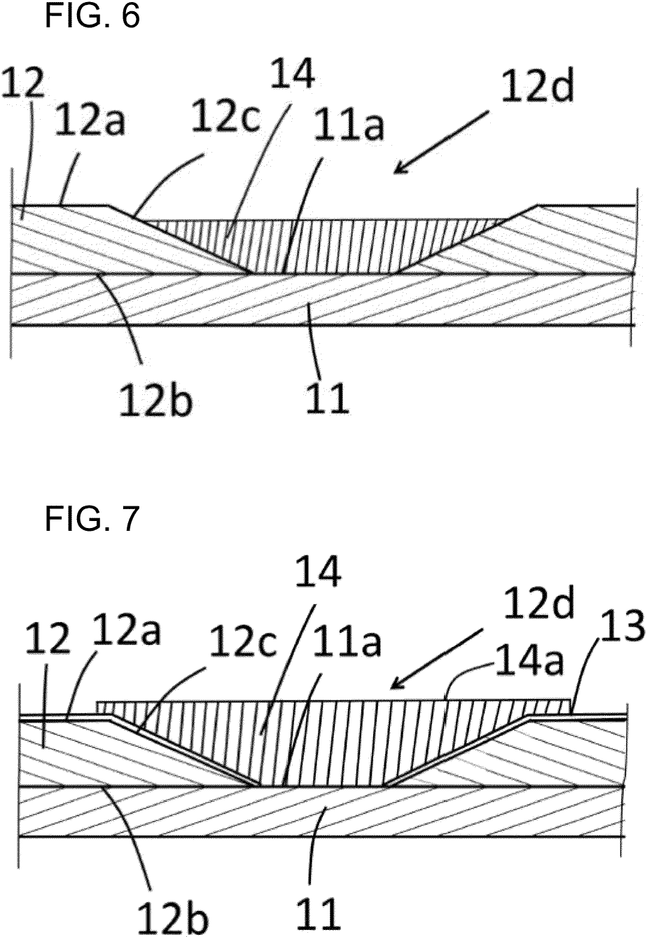

FIG. 6 is a diagram schematically illustrating a section of the opening portion of the mask illustrated in FIG. 3. In the opening portion 12d of the mask 12 disposed above the first surface 11a of the base 11, the angle 12e (mask inclination angle) formed between the second surface 12b and the inclined surface 12c of the mask 12 that is in contact with the first surface 11a of the base 11 is assumed to fall within a range of 10° < the inclination angle 12e < 90°. Also, in the present embodiment, the inclination angle 12e formed between the second surface 12b and the inclined surface 12c of the mask 12 preferably falls within a range of 10° < the inclination angle 12e < 90°, and the inclination angle 12e is more preferably equal to or less than 70° and is most preferably equal to or greater than 20° and equal to or less than 70°. As illustrated in FIG. 6, the semiconductor film 14 including a first surface 14a, a second surface 14b with a smaller area than the first area 14a, and an inclined surface 14c between the first surface 14a and the second surface 14b may be formed, and the first surface 14a and the second surface 14b of the semiconductor film 14 may be parallel surfaces that are parallel to each other, by causing the semiconductor film 14 to grow on the base 11 with the mask 12 including the inclined surface 12c disposed thereon. In the embodiment of the present disclosure, the mask may be formed of a material with a higher electrical insulating property than the semiconductor film 14. For example, an insulator such as silicon dioxide (SiO₂) or silicon nitride (Si₃N₄) may be used as a mask material. Also, a protective film 13 may be disposed on the first surface 12a and the inclined surface 12c of the mask 12 as illustrated in FIG. 4. Prevention of impurities such as silicon contained in the mask material from being diffused may be expected by disposing the protective film 13.

Note that in regard to the semiconductor film 14, the first surface 14a of the semiconductor film 14 may be formed at a lower position than the first surface 12a of the mask 12 as illustrated in FIG. 6.

The semiconductor film includes the first surface 14a, the second surface 14b on the side opposite to the first surface 14a, and the inclined surface 14c that is located between the first surface 14a and the second surface 14b, the mask 12 includes the first surface 12a, the second surface 12b on the side opposite to the first surface 12a, and the side surface including the inclined surface 12c that is located between the first surface 12a and the second surface 12b, and further, the first surface 14a of the semiconductor film 14 may be formed at a lower position than the first surface 12a of the mask 12. Note that a p type semiconductor film may also be caused to epitaxially grow on the first surface 14a of the semiconductor film 14 after the semiconductor film 14 is caused to epitaxially grow as an n- type semiconductor as illustrated in FIG. 6. The p type semiconductor film may also be formed such that a first surface of the p type semiconductor film and the first surface 12a of the mask 12 are at the same height. In this manner, according to the manufacturing method in the embodiment of the present disclosure, the semiconductor device having a bevel structure at a peripheral end portion of the multilayer structure including semiconductor layers of different conductive types may be easily formed. Also, according to the embodiment of the present disclosure, the bevel structure may be obtained at the end portion of the semiconductor film where an electric field is likely to concentrate in general, and further, a semiconductor crystal with less dislocation is obtained through lateral growth near the end portion where the bevel structure is provided rather than the center portion of the semiconductor film, which leads to an improvement in semiconductor properties. Note that a semiconductor film may also be formed using a base including a crystal that has grown in the lateral direction by providing irregularity on the substrate 16 and forming a crystalline layer such as a buffer layer thereon when the base 11 is prepared, although description will be given later. The semiconductor film including a small amount of dislocation in a level equivalent to that near the end portion where the bevel structure is provided may be formed even at the center portion of the semiconductor film, and the semiconductor device with higher strength against electrical breakdown may be obtained, by incorporating two or more crystal formation processes including lateral growth in the formation of the semiconductor film.

Also, according to another embodiment of the present disclosure, the semiconductor film 14 may also be formed such that the first surface 14a of the semiconductor film 14 and the first surface 12a of the mask 12 are at the same height as illustrated in FIG. 10. The semiconductor film 14 includes the first surface 14a, the second surface 14b on the side opposite to the first surface 14a, and the end portion that is located between the first surface 14a and the second surface 14b, and the mask 12 includes the first surface 12a, the second surface 12b on the side opposite to the first surface 12a, and the side surface including the inclined surface 12c that is located between the first surface 12a and the second surface 12b. In the present embodiment, the inclined surface 14c of the semiconductor film 14 and the inclined surface 12c of the mask 12 in the opposite direction are engaged, and the first surface 14a of the semiconductor film 14 and the first surface 12a of the mask 12 of the insulator are in the same plane. The first surface 14a of the semiconductor film 14 and/or the first surface 12a of the mask 12 may be ground through chemical mechanical polishing (CMP), for example, to be in the same plane after the semiconductor film 14 is caused to epitaxially grow.

In the present embodiment, the inclined surface of the semiconductor film 14 and the inclined surface of the mask 12 are in close contact with each other. In this case, the electrode 15 is formed to cover at least a part of the first surface 14a of the semiconductor film 14 and at least a part of the first surface 12a of the mask 12 as illustrated in FIG. 10, and the electrode 15 may be formed on the flat surface including the first surface 14a of the semiconductor film 14 and the first surface 12a of the mask 12, which not only enables the electrode to be easily formed but also enables the semiconductor device to be flattened and thinned while including the bevel structure at the end portion of the semiconductor film. Note that concentration of an electric field at the electrode end portion may be avoided by forming the electrode such that the end portion 15c thereof is located above the mask 12 with a higher electrical insulating property than the semiconductor film.

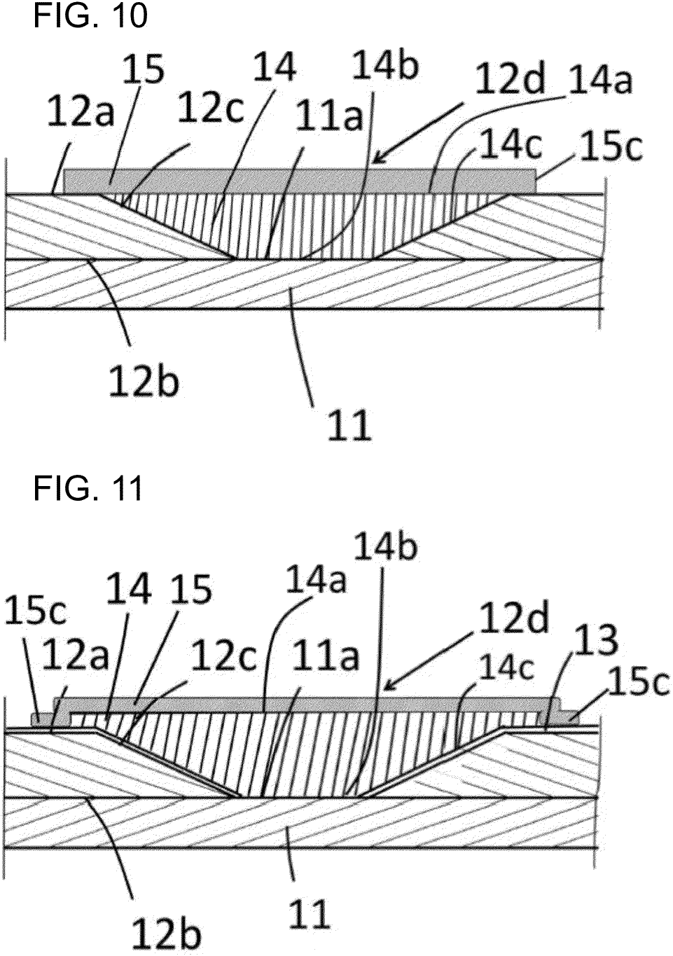

Furthermore, the first surface 14a of the semiconductor film 14 may be formed at a higher position than the first surface 12a of the mask 12 as illustrated in FIG. 11. The semiconductor film 14 includes the first surface 14a, the second surface 14b on the side opposite to the first surface 14a, and the inclined surface 14c at the end portion that is located between the first surface 14a and the second surface 14b, the mask 12 includes the first surface 12a, the second surface 12b that is in contact with the first surface 11a of the base 11 on the side opposite to the first surface 12a, and the side surface including the inclined surface 12c that is located between the first surface 12a and the second surface 12b, and further, the first surface 14a of the semiconductor film 14 is formed at a higher position than the first surface 12a of the mask 12. In the present embodiment, the annular inclined surface 14a of the semiconductor film 14 and the annular inclined surface 12c of the mask 12 in the opposite direction are engaged. In the present embodiment, the inclined surface of the semiconductor film 14 and the inclined surface of the mask 12 are in close contact with each other via the protective film 13 disposed above the mask 12. Furthermore, the electrode 15 is formed to cover at least a part of the first surface 14a of the semiconductor film 14 and at least a part of the first surface 12a of the mask 12 as illustrated in FIG. 11, and concentration of an electric field at the electrode end portion may be avoided by forming the electrode 15 such that the end portion 15c thereof is located above the mask 12 with a higher electrical insulating property than the semiconductor film 14. In the present embodiment, the electrode 15 is formed beyond the inclined surface 14c at the end portion from the first surface 14a of the semiconductor film 14, and the end portion 15c of the electrode 15 is located above the first surface 12a of the mask 12 as illustrated in FIG. 11.

Furthermore, the first surface 14a of the semiconductor film 14 may be formed at a lower position than the first surface 12a of the mask 12 as illustrated in FIG. 12. The semiconductor film 14 includes the first surface 14a, the second surface 14b on the side opposite to the first surface 14a, and the inclined surface 14c at the end portion that is located between the first surface 14a and the second surface 14b, the mask 12 includes the first surface 12a, the second surface 12b that is in contact with the first surface 11a of the base 11 on the side opposite to the first surface 12a, and the side surface including the inclined surface 12c that is located between the first surface 12a and the second surface 12b, and further, the first surface 14a of the semiconductor film 14 is formed at a lower position than the first surface 12a of the mask 12. In the present embodiment, the annular inclined surface 14c of the semiconductor film 14 and the annular inclined surface 12c of the mask 12 in the opposite direction are engaged, and the inclined surface 14a of the semiconductor film 14 and the inclined surface 12c of the mask 12 are in close contact with each other. Furthermore, the electrode 15 is formed to cover at least a part of the first surface 14a of the semiconductor film 14 and at least a part of the first surface 12a of the mask 12 as illustrated in FIG. 12, and concentration of an electric field at the electrode end portion may be avoided by forming the electrode 15 such that the end portion 15c thereof is located above the mask 12 with a higher electrical insulating property than the semiconductor film 14.

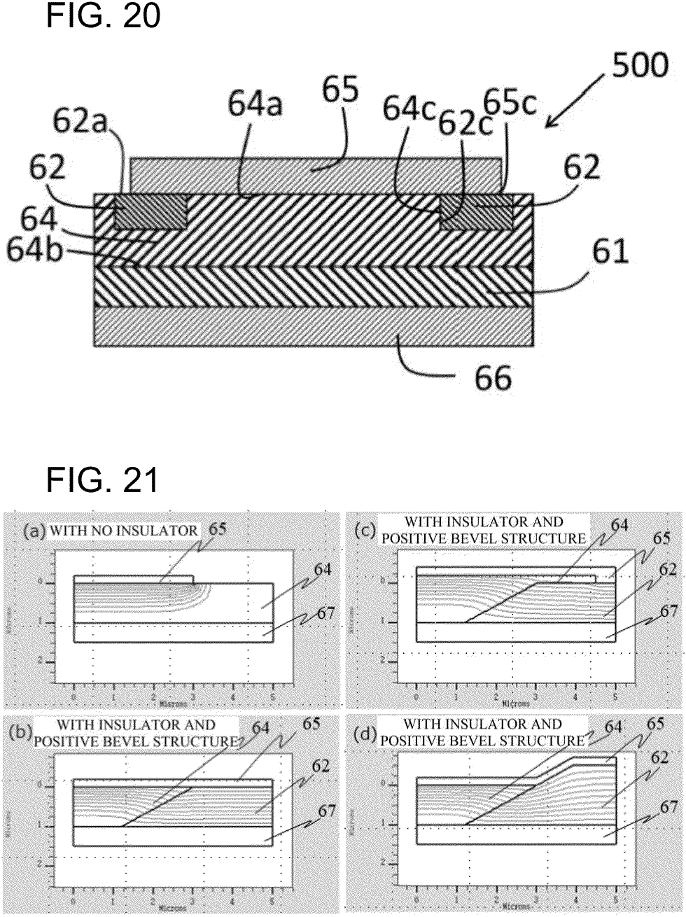

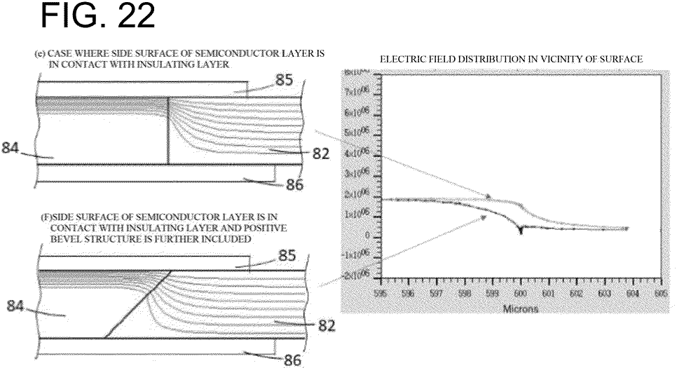

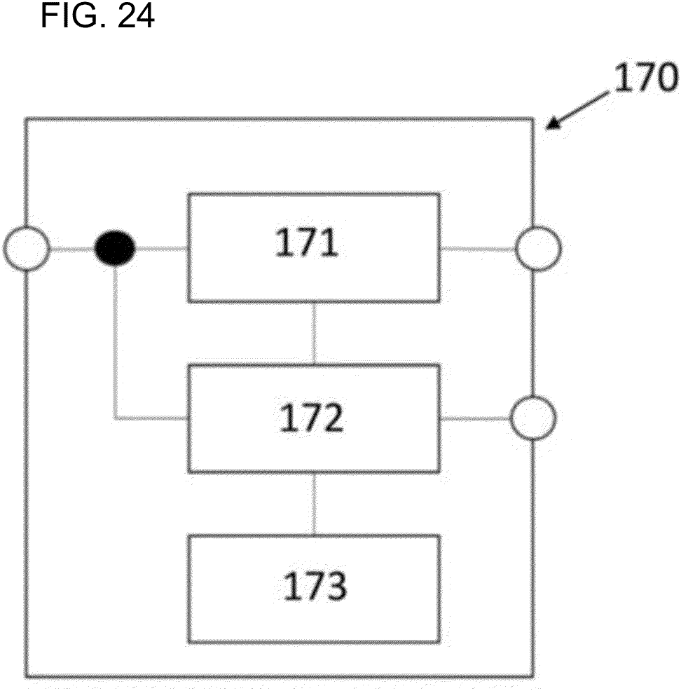

A diagrammatic view of results of simulating electric field distribution at 100 V in a case where Ga₂O₃ is used as the semiconductor film (n- type semiconductor layer) 64, Ga₂O₃ is used as the second semiconductor layer (n+ type semiconductor layer) 67, SiO₂ is used as the non-conductive layer (insulating layer) 62, and the inclination angle 64e is set to 29° in the semiconductor device 100 in FIG. 17 is shown in FIG. 21. Note that the diagrammatic view of the results of simulating electric field distribution in a semiconductor device (a) which is a semiconductor device with no bevel structure and includes a termination of a first electrode located above a semiconductor film according to a comparative example and in semiconductor devices (b) to (d) which are obtained in the embodiment of the present disclosure, have bevel structures, and include terminations of first electrodes 65 located above insulators 62 is illustrated in FIG. 21. The semiconductor device (b) is a semiconductor device which is produced by the manufacturing process as illustrated in FIG. 10, includes an insulator, and has a bevel structure according to one embodiment of the present disclosure, and has the bevel structure at an end portion of a semiconductor film 64. The first surface of the semiconductor film 64 and the first surface of the insulator 62 are in the same plane in the semiconductor device (b), and termination of the first electrode 65 disposed on the first surface of the semiconductor film 64 and the first surface of the insulator 62 that are in the same plane is located above the insulator 62. Additionally, a second electrode (not illustrated) is disposed on the side opposite to the first electrode 65. The semiconductor device (c) has a bevel structure at an end portion of a semiconductor film, the first surface of the semiconductor film 64 is located at a higher position than a first surface of an insulator 62 in the semiconductor device (c), a first electrode 65 is formed beyond the inclined surface at the end portion from the first surface of the semiconductor film 64, and the end portion of the first electrode 65 is located above the first surface of the insulator 62. The semiconductor device (d) is a semiconductor device that is produced by the manufacturing process as illustrated in FIG. 12 and has a bevel structure according to one embodiment of the present disclosure, and has the bevel structure at an end portion of a semiconductor film. A first surface of a semiconductor film 64 is located at a lower position than a first surface of an insulator 62 in the semiconductor device (d), a first electrode 65 is formed beyond the inclined surface at the end portion from the first surface of the semiconductor film 64, and the end portion of the first electrode 65 is located above the first surface of the insulator 62. Although electric field concentrates at the end portion of the electrode 65 located above the semiconductor film 64 in the semiconductor device (a) with no bevel structure, concentration of an electric field is not observed in the semiconductor devices (b) to (d) having the bevel structures. FIG. 23 illustrates results of simulating electric field distribution at 10 nm below the first electrodes at 100 V in the semiconductor device (a) with no bevel structure and the semiconductor devices (b) to (d) having the bevel structures, which are illustrated in FIG. 21, and it has been found that the semiconductor devices obtained in the embodiment of the present disclosure have a structure in which electrical breakdown is unlikely to occur in the vicinity of the surfaces of the semiconductors, that is, at the rectifier junction interfaces between the semiconductors and the electrodes.

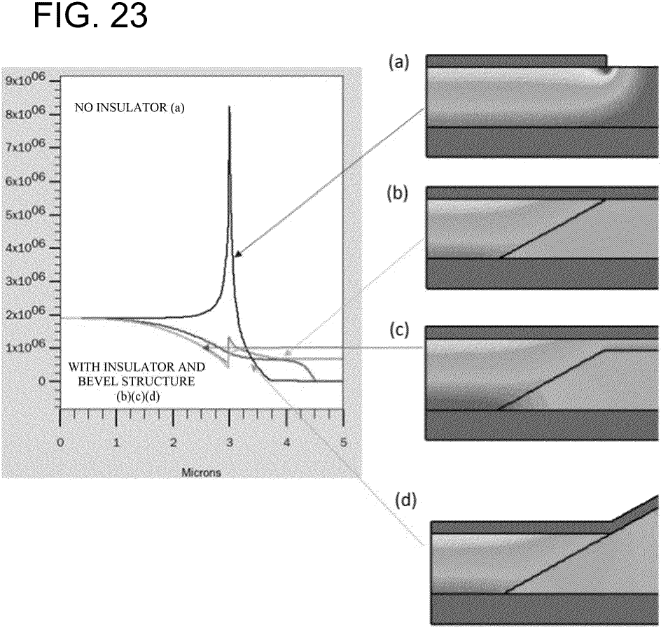

In comparison with the simulation of the semiconductor device with the structure in FIG. 21a (with no insulator that is in contact with the side surface of the semiconductor layer; with no positive bevel structure), the structure in (e) (with an insulator that is in contact with the side surface of the semiconductor layer; with no positive bevel structure) and the structure in (f) (with an insulator that is in contact with the side surface of the semiconductor layer; with a positive bevel structure) are simulated similarly to FIG. 21. The termination of the first electrode 65 is located above the semiconductor film 64 in the structure in (a) of FIG. 21, while the terminations of the first electrodes 65 are located above the insulators 62 in the structures in (e) and (f) of FIG. 22. It has been found through comparison with the structure in (e) that according to the structure in (f) having a positive bevel structure, concentration of an electric field is further alleviated and the semiconductor device has a structure in which electrical breakdown is less likely to occur at the surface of the semiconductor. However, it has been found that in the case of (e) where a positive bevel structure is not formed, concentration of an electric field is alleviated, and a structure in which electrical breakdown is less likely to occur at the surface of the semiconductor is achieved, as compared with the case where the termination of the first electrode 65 is located above the semiconductor layer in FIG. 21a, by the termination of the first electrode 65 being located above the insulator 62.

In the embodiment of the present disclosure, a buffer layer including a stress buffering layer or the like may be provided at least as a part of the base on the substrate, and in the case where the buffer layer is provided, the recessed and projecting portions may be formed even on the buffer layer. Also, in the embodiment of the present disclosure, the substrate preferably includes the buffer layer at a part or entirety of the surface thereof. A means for forming the buffer layer is not particularly limited and may be a known means. Examples of the formation means include a spray method, a mist CVD method, an HVPE method, an MBE method, an MOCVD method, and a sputtering method. The buffer layer is formed by the mist CVD method in the present disclosure, which is preferable since more excellent film quality of the crystalline film formed on the buffer layer may be achieved and particularly, a crystal defect such as tilting may be curbed. Hereinafter, a suitable mode in which the buffer layer is formed by the mist CVD method will be described in more detail.

The buffer layer may be formed suitably by atomizing a raw material solution to obtain atomized liquid droplets (atomizing process), transporting the obtained atomized liquid droplets to the substrate using carrier gas (transport process), and causing a thermal reaction of the atomized liquid droplets (a mist or liquid droplets)by a part or entirety of the surface of the substrate and/or the base (buffer layer formation process), for example.

### Atomization Process

The atomization process atomizes the raw material solution and obtains the atomized droplets. The means of atomizing the raw material solution is not limited to a particular means as long as the means can atomize the raw material solution, and may be a publicly known means; in the present disclosure, an atomizing means using ultrasonic waves is preferable. The atomized droplets obtained using ultrasonic waves are preferable because the initial velocity thereof is zero, which allows them to be suspended in the air, and are very suitable because they are mist that is suspended in the space and can be conveyed as gas, not being sprayed like a spray, for example, and therefore cause no damage by collision energy. The droplet size is not limited to a particular size and may be a droplet of about a few mm; the droplet size is preferably 50 µm or less and more preferably 0.1 to 10 µm.

### Raw Material Solution

The raw material solution is not limited to a particular raw material solution as long as the raw material solution is a solution and allows the buffer layer, the crystalline layer and/or the semiconductor layer to be obtained by mist CVD. Examples of the raw material solution include an aqueous solution of an organometallic complex (for example, an acetylacetonato complex) or a halide (for example, fluoride, chloride, bromide, or iodide) of metal for atomization. The metal for atomization is not limited to particular metal, and examples of such metal for atomization include one or two or more types of metal selected from aluminum, gallium, indium, iron, chromium, vanadium, titanium, rhodium, nickel, cobalt, iridium and so forth. In the present disclosure, the metal for atomization preferably contains at least gallium, indium, or aluminum and more preferably contains at least gallium. The content of the metal for atomization in the raw material solution is not limited to a particular content unless it interferes with the object of the present disclosure; the content of the metal for atomization in the raw material solution is preferably 0.001 to 50 mol% and more preferably 0.01 to 50 mol%.

Moreover, it is also preferable that the raw material solution contains dopant. By making the raw material solution contain dopant, it is possible to easily control the electrical conductivity of the buffer layer, the crystalline layer and/or the semiconductor layer without a breakdown of a crystal structure without performing ion implantation or the like. In the present disclosure, the dopant is preferably tin, germanium, or silicon, more preferably tin or germanium, and most preferably tin. In general, the concentration of the dopant may be about 1×10¹⁶/cm³ to 1×10²²/cm³; the concentration of the dopant may be set at a low concentration of about 1×10¹⁷/cm³ or less or the raw material solution may be made to contain the dopant at a high concentration of about 1×10²⁰/cm³ or more. In the present disclosure, the concentration of the dopant is preferably 1×10²⁰/cm³ or less and more preferably 5×10¹⁹/cm³ or less.

A solvent of the raw material solution is not limited to a particular solvent and may be an inorganic solvent such as water, an organic solvent such as alcohol, or a mixed solvent of an inorganic solvent and an organic solvent. In the present disclosure, the solvent preferably contains water, is more preferably water or a mixed solvent of water and alcohol, and is most preferably water. More specifically, examples of the water include pure water, ultrapure water, tap water, well water, mineral water, mineralized water, hot spring water, spring water, fresh water, and seawater; in the present disclosure, ultrapure water is preferable.

### Conveying Process

In the conveying process, the atomized droplets are conveyed into a film formation chamber by carrier gas. The carrier gas is not limited to particular carrier gas unless it interferes with the object of the present disclosure, and suitable examples of the carrier gas include oxygen, ozone, inert gas such as nitrogen and argon, reducing gas such as hydrogen gas and forming gas, or the like. Moreover, one type of carrier gas may be used; two or more types of carrier gas may be used and dilution gas (for example, 10-fold dilution gas) with a decreased flow rate, for example, may be additionally used as second carrier gas. Furthermore, instead of one carrier gas supply point, two or more carrier gas supply points may be provided. The flow rate of carrier gas is not limited to a particular flow rate and is preferably 0.01 to 20 L/min and more preferably 1 to 10 L/min. When dilution gas is used, the flow rate of the dilution gas is preferably 0.001 to 2 L/min and more preferably 0.1 to 1 L/min.

### Formation Process of Buffer Layer, Crystalline Layer, and/or Semiconductor Layer

In the formation process of the buffer layer, the crystalline layer, and/or the semiconductor layer (hereinafter, also referred to as a crystalline layer), the crystalline layer is formed on the substrate by causing a thermal reaction of the atomized liquid droplets inside the film formation chamber. The thermal reaction may be any thermal reaction as long as the mist or the liquid droplets thermally cause a reaction, and reaction conditions and the like are also not particularly limited unless they interfere with the present disclosure. In this process, the thermal reaction is typically caused at a temperature that is equal to or greater than a solvent evaporation temperature, the temperature is preferably equal to or less than a temperature that is not excessively high (1000° C., for example), is more preferably equal to or less than 650° C., and is most preferably from 400° C. to 650° C. Also, although the thermal reaction may be caused in any atmosphere out of under vacuum, in a non-oxygen atmosphere, in a reducing gas atmosphere, and in an oxygen atmosphere and may be caused under any condition out of under an atmospheric pressure, under a pressure, and under a reduced pressure unless it interferes with the present disclosure, the thermal reaction is preferably caused under an atmospheric pressure in the present disclosure. Note that the thickness of the crystalline layer may be set by adjusting the formation time.

The crystalline layer may be formed as a buffer layer on a part or entirety of the surface of the substrate to obtain a base, the aforementioned mask may be disposed on the crystalline layer of the base, and the semiconductor film may be caused to epitaxially grow as described above. Since the recessed/projecting portions are provided on the substrate and the crystalline layer is then formed when the base is prepared, the crystalline layer including lateral growth may be obtained, a defect such as tilting in the crystalline layer as the buffer layer may be further reduced, and more excellent film quality is achieved, by forming the crystalline layer. Also, the crystalline layer may also be used as the semiconductor layer of the semiconductor device as described above, and further excellent film quality of the semiconductor film may be achieved by forming the semiconductor film having a bevel structure on the semiconductor layer.

Also, although the crystalline layer is not particularly limited, the crystalline layer preferably contains a metal oxide as a major component in one embodiment of the present disclosure. Examples of the metal oxide include metal oxides or the like containing one kind or two or more kinds of metal selected from aluminum, gallium, indium, iron, chromium, vanadium, titanium, rhodium, nickel, cobalt, iridium, and the like. In the present disclosure, the metal oxide preferably contains one kind or two or more kinds of elements selected from indium, aluminum, and gallium, more preferably contains at least indium or/and gallium, and most preferably contains at least gallium. According to one embodiment of the film formation method of the present disclosure, the buffer layer may contain a metal oxide as a major component, and the metal oxide included in the buffer layer may contain gallium and aluminum in a smaller amount than the amount of gallium. Also, according to one embodiment of the film formation method of the present disclosure, the buffer layer may include a superlattice structure. Note that the “major component” in the present disclosure means that preferably not less than 50%, more preferably not less than 70%, and further preferably not less than 90% of the metal oxide is contained with respect to all components in the buffer layer in terms of an atomic ratio and means that the content of the metal oxide may be 100%. Although the crystal structure of the metal oxide is not particularly limited, the crystal structure is preferably a corundum structure or a β-gallia structure and is more preferably a corundum structure according to one embodiment of the present disclosure. Also, although the crystalline film and the buffer layer may have mutually the same major component or different major components unless it interferes with the present disclosure, the crystalline film and the buffer layer preferably have mutually the same major component in the embodiment of the present disclosure.

The semiconductor film obtained by the manufacturing method according to the present disclosure may be suitably used for a semiconductor device, in particular, and is especially useful for a power device. Examples of the semiconductor device formed using the crystalline film include transistors and TFTs such as MIS and HEMT, Schottky barrier diodes and junction barrier Schottky diodes using semiconductor-metal junctions, and the like. In the embodiment of the present disclosure, there is an advantage that the semiconductor film may be used for a semiconductor device or the like as it is by causing the semiconductor film to epitaxially grow on a base with the mask formed thereon. Also, the semiconductor film may be applied to a semiconductor device or the like after a known means such as peeling-off from the base or the like is used.

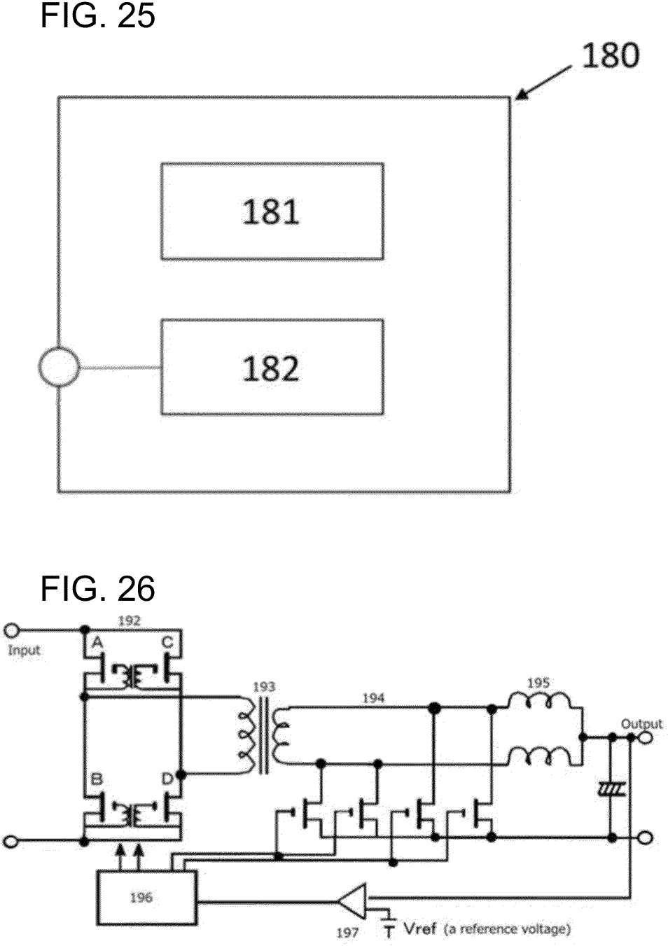

The semiconductor device according to the present disclosure is suitably used as a power module, an inverter, or a converter by further using a known method in addition to the above items, and further, the semiconductor device is suitably used for a semiconductor system using a power supply device, for example. The power supply device may be produced by connecting the semiconductor device to a wiring pattern or the like by using a known method. FIG. 24 illustrates an example of a power supply system. In FIG. 24, a power supply system 170 is configured using a plurality of power supply devices 171 and 172 and a control circuit 173. The power supply system 182 may be used in combination with an electronic circuit 181 for a system device 180 as illustrated in FIG. 25. Note that an example of a power supply circuit diagram of the power supply device is illustrated in FIG. 26. FIG. 26 illustrates a power supply circuit of a power supply device including a power circuit and a control circuit, a DC voltage is switched at a high frequency by an inverter 19 (configured of MOSFETs A to D) and is converted into AC, insulation and transformation are then performed by a transformer 193, rectification is performed by a rectifier MOSFET, smoothing is then performed thereon by a DCL 195 (smoothing coils L1 and L2) and a capacitor, and a direct current voltage is output. At this time, a voltage comparator 197 compares the output voltage with a reference voltage, and a PWM control circuit 196 controls the inverter 192 and the rectifier MOSFET 194 to achieve a desired output voltage.

### Example

Although an example of the present disclosure will be described below, the present disclosure is not limited thereto.

### Example

### 1. Preparation of Base (Formation of Buffer Layer)

### 1-1. Mist CVD Device

A mist CVD device 19 used in the present example will be described using FIG. 8. The mist CVD device 19 includes a carrier gas supply source 22a that supplies carrier gas, a flow regulating valve 23a that is for adjusting the flow rate of the carrier gas fed from the carrier gas supply source 22a, a carrier gas (diluted) source 22b that supplies the carrier gas (diluted), a flow regulating valve 23b that is for adjusting the flow rate of the carrier gas (diluted) fed from the carrier gas (diluted) source 22b, a mist generation source 24 that accommodates a raw material solution 24a, a container 25 that contains water 25a therein, an ultrasonic vibrator 26 that is attached to a bottom surface of the container 25, a film formation chamber 30, a supply pipe 27 that connects the mist generation source 24 to the film formation chamber 30 and is made of quartz, a hot plate 28 that is placed in the film formation chamber 30, and an exhaust port 29. A target of film formation (film formation target) 20 is placed on the hot plate 28.

### 1-2. Production of Raw Material Solution (Formation of Buffer Layer)

Gallium acetylacetonate was mixed into ultrapure water, the aqueous solution was adjusted to contain 0.05 mol/L of gallium acetylacetonate, and at this time, 5% of hydrobromic acid was caused to be contained in terms of a volume ratio, and this was obtained as a raw material solution.

### 1-3. Preparation for Film Formation (Formation of Buffer Layer)

The raw material solution 24a obtained in 1-2 above was accommodated in the mist generation source 24. Then, as a film formation target 20, a sapphire substrate was placed on the hot plate 28, the hot plate 28 was caused to operate, and the temperature of the film formation target was raised to 550° C. Next, the flow regulating valves 23a and 23b were opened to supply carrier gas from the carrier gas sources 22a and carrier gas (diluted) source 22b into the film formation chamber 30, the atmosphere in the film formation chamber 30 was sufficiently substituted with the carrier gas, and the flow rate of the carrier gas and the flow rate of the carrier gas (diluted) were then adjusted to 0.8 L/min and 0.2 L/min, respectively. Note that oxygen was used as the carrier gas.

### 1-4. Film Formation (Formation of Buffer Layer)

Next, the ultrasonic vibrator 26 was caused to vibrate at 2.4 MHz, the vibration was caused to propagate to the raw material solution 24a through the water 25a, the raw material solution 24a was thereby atomized, and fine raw material particles were generated. The fine raw material particles were introduced into the film formation chamber 30 by the carrier gas and caused reaction inside the film formation chamber 30 at 550° C., and a buffer layer (Ga₂O₃ buffer layer having a corundum structure) was formed on the substrate 20, thereby obtaining a base. Note that the film formation time was 10 minutes and the film thickness was 0.1 µm.

### 2. Formation of Mask

### 2-1. Formation of Mask Layer

A mask layer of silicon oxide (SiO₂) was formed on the buffer layer obtained in 1-4 described above using liquid tetraethyl orthosilicate by a plasma enhanced CVD method. The film thickness of the mask layer was 1.3 µm.

### 2-2. Formation of Photoresist Layer

A photoresist layer was formed on at least a part of the mask layer obtained in 2-1 described above by photolithography.

### 2-3. Formation of Mask Having Inclined Surface

An opening portion was formed in the SiO₂ mask layer having the photoresist layer obtained in 2-2 described above using a buffered hydrofluoric acid (BHF) at a room temperature. The opening portion in the mask layer having the inclined surface at an end portion is formed by undercut of isotropic wet etching. The angle (inclination angle) formed between the surface of the mask layer in contact with the base and the inclined surface was formed at 29°, and a base with the mask including the inclined surface disposed thereon was obtained.

### 3. Formation of Semiconductor Film

### 3-1. Film Formation Device

A device capable of causing epitaxial growth may be used as the film formation device according to the embodiment of the present disclosure, and the mist CVD device illustrated in FIG. 8 was used as an example of such a device.

### 3-2. Production of Raw Material Solution (Formation of Semiconductor Film)

Gallium bromide was mixed into ultrapure water, the aqueous solution was adjusted to contain 0.05 mol/L of gallium, and at this time, 20% of hydrobromic acid was caused to be contained in terms of a volume ratio, and this was obtained as a raw material solution.

### 3-3. Preparation for Film Formation (Formation of Semiconductor Film)

The raw material solution 24a obtained in 3-2 described above was accommodated in the mist generation source 24. Next, the base which was obtained in 2-3 and included the mask including the inclined surface disposed thereon was placed as the film formation target 20 on the hot plate 28, and the temperature of the base was raised to 630° C. Then, the flow regulating valves 23a and 23b were opened to supply carrier gas from the carrier gas source 22a and the carrier gas (diluted) source 22b into the film formation chamber 30, the atmosphere in the film formation chamber 30 was sufficiently substituted with the carrier gas, and the flow rate of the carrier gas and the flow rate of the carrier gas (diluted) were then adjusted to 0.8 L/min and 0.2 L/min, respectively. Note that nitrogen was used as the carrier gas.

### 3-4. Film Formation (Formation of Semiconductor Film)

Next, the ultrasonic vibrator 26 was caused to vibrate at 2.4 MHz, the vibration was caused to propagate to the raw material solution 24a through the water 25a, the raw material solution 24a was thereby atomized, and fine raw material particles were generated. The fine raw material particles were introduced into the film formation chamber 30 by the carrier gas and caused reaction inside the film formation chamber 30 at 630° C., and a semiconductor film was formed on the base 20 which was obtained in 2-3 described above and included the mask including the inclined surface disposed thereon. Note that the film formation time was 3.5 hours.

### 3-5. Evaluation

The semiconductor film obtained in 3-4 described above was a well-tuned film with no cracking and abnormal growth. The obtained film was subjected to 2θ/ω scanning at an angle of 15 degrees to 95 degrees using a thin-film XRD diffracting device, and the film was identified. Measurement was performed using CuKα radiation. As a result, the thus obtained film was α—Ga₂O₃. Also, an inclined surface was formed at the end portion of the semiconductor film of α—Ga₂O₃ as illustrated in FIG. 9. Note that the Pt coating on the SiO₂ and the semiconductor film was provided for the purpose of facilitating observation. A Schottky contact including a positive bevel structure as a termination structure may be obtained by forming a Schottky electrode on SiO₂ and the semiconductor film. Also, it was found that the region near the end portion of the semiconductor film contained crystals having grown in the lateral direction and that the semiconductor film with less dislocation was obtained near the end portion where the positive bevel structure was formed.

### Industrial Applicability

Although the manufacturing method according to the present disclosure may be used in any fields of semiconductors (for example, compound semiconductor electronic devices and the like), electronic components and electrical equipment components, optical and electrophotography-related devices, industrial members, and the like, the manufacturing method is particularly useful for manufacturing and the like of semiconductor devices including Schottky junctions and semiconductor devices including power semiconductors used for power supplies or the like.

The embodiments of the present invention are exemplified in all respects, and the scope of the present invention includes all modifications within the meaning and scope equivalent to the scope of claims.

### Reference Signs List

11 Base
11a First surface of base
11b Second surface of base
12 Mask
12a First surface of mask
12b Second surface of mask
12c Inclined surface of mask
12d Opening portion of mask
12e Inclination angle of mask
12′ Second mask
13 Protective film
14 Semiconductor film
14a First surface of semiconductor film
14b Second surface of semiconductor film
14c Inclined surface of semiconductor film
15 Electrode
15c End portion of electrode 15
16 Substrate
17 Crystalline layer
18 Crystalline layer
19 Mist CVD device
20 Film formation target
22a Carrier gas source
22b Carrier gas (diluted) source
23a Flow regulating valve
23b Flow regulating valve
24 Mist generation source
24a Raw material solution
25 Container
25a Water
26 Ultrasonic vibrator
27 Supply pipe
28 Hot plate
30 Film formation chamber
50 Halide vapor phase epitaxy (HVPE) device
51 Reaction chamber
52a Heater
52b Heater
53a Halogen-containing raw material gas supply source
53b Metal-containing raw material gas supply pipe
54a Reactive gas supply source
54b Reactive gas supply pipe
55a Oxygen-containing raw material gas supply source
55b Oxygen-containing raw material gas supply pipe
56 Substrate holder
57 Metal source
58 Protective sheet
59 Gas discharge portion
61 Crystalline layer
62 Non-conductive layer
62a First surface of non-conductive layer 62
62b Second surface of non-conductive layer 62
62c Inclined surface of non-conductive layer 62
63 Protective film
64 Semiconductor film
64a First surface of semiconductor film
64b Second surface of semiconductor film
64c Inclined surface of semiconductor film
64e Inclination angle formed by first surface 64a and inclined surface 64c of semiconductor film
64f First region of semiconductor film
64g Second region of semiconductor film
65 First electrode
65c End portion of first electrode
66 Second electrode
67 p type semiconductor portion
90 Rectifier junction interface
100 Semiconductor device
170 Power supply system
171 Power supply device
172 Power supply device
173 Control circuit
180 System device
181 Electronic circuit
182 Power supply system
192 Inverter
193 Transformer
194 MOSFET
195 DCL
196 PWM control circuit
197 Voltage comparator
200 Semiconductor device
300 Semiconductor device
400 Semiconductor device
500 Semiconductor device

What is claimed is:

1. A semiconductor device comprising:
a semiconductor layer;
a non-conductive layer that is in contact with at least a part of a side surface of the semiconductor layer directly or via another layer; and
a Schottky electrode that is disposed on the semiconductor layer and the non-conductive layer, an end portion of the Schottky electrode being located above the non-conductive layer.

2. The semiconductor device according to claim 1, wherein the non-conductive layer includes a first surface on a side of the Schottky electrode, a second surface that is located on a side opposite to the first surface, and a side surface that is located between the first surface and the second surface, the semiconductor layer includes a first surface on the side of the Schottky electrode, a second surface that is located on the side opposite to the first surface, and the side surface that is located between the first surface and the second surface, and the second surface of the semiconductor layer and the second surface of the non-conductive layer are in the same plane.

3. The semiconductor device according to claim 1, wherein the non-conductive layer includes a first surface on a side of the Schottky electrode, a second surface that is located on a side opposite to the first surface, and a side surface that is located between the first surface and the second surface, the semiconductor layer includes a first surface on the side of the Schottky electrode, a second surface that is located on the side opposite to the first surface, and the side surface that is located between the first surface and the second surface, and the second surface of the non-conductive layer is located at a position closer to the Schottky electrode than the second surface of the semiconductor layer.

4. The semiconductor device according to claim 1, wherein the semiconductor layer contains at least gallium.

5. The semiconductor device according to claim 1, wherein the semiconductor layer contains a crystalline metal oxide as a major component.

6. The semiconductor device according to claim 1, wherein the semiconductor layer contains a mixed crystal of crystalline gallium oxide or gallium oxide.

7. The semiconductor device according to claim 1, wherein the semiconductor layer has a corundum structure.

8. The semiconductor device according to claim 1, wherein the semiconductor layer includes a first surface on a side of the Schottky electrode and a second surface that is located on a side opposite to the first surface, the non-conductive layer includes a first surface on the side of the Schottky electrode and a second surface that is located on the side opposite to the first surface, and the first surface of the semiconductor layer and the first surface of the non-conductive layer are in the same plane.

9. The semiconductor device according to claim 1, wherein the semiconductor layer includes a first surface on a side of the Schottky electrode and a second surface that is located on a side opposite to the first surface, the non-conductive layer includes a first surface on the side of the Schottky electrode and a second surface that is located on the side opposite to the first surface, and the first surface of the semiconductor layer is located at a higher position than the first surface of the non-conductive layer.

10. The semiconductor device according to claim 1, wherein the semiconductor layer includes a first surface on a side of the Schottky electrode and a second surface that is located on a side opposite to the first surface, the non-conductive layer includes a first surface on the side of the Schottky electrode and a second surface that is located on the side opposite to the first surface, and the first surface of the non-conductive layer is located at a higher position than the first surface of the semiconductor layer.

11. The semiconductor device according to claim 1, wherein the side surface of the semiconductor layer includes an inclined surface.

12. The semiconductor device according to claim 11, wherein the semiconductor layer includes a first surface on a side of the Schottky electrode and a second surface that is located on a side opposite to the first surface and includes the side surface that is located between the first surface and the second surface, and the inclined surface of the semiconductor layer is an inclined surface with a film thickness increasing from the first surface toward the second surface.

13. The semiconductor device according to claim 11, wherein the semiconductor layer includes a first surface on a side of the Schottky electrode and a second surface that is located on a side opposite to the first surface and includes the side surface that is located between the first surface and the second surface, and an angle formed by the first surface of the semiconductor layer and the inclined surface of the semiconductor layer is equal to or greater than 20° and equal to or less than 70°.

14. The semiconductor device according to claim 11, wherein the non-conductive layer includes a first inclined surface, the side surface of the semiconductor layer includes the inclined surface as a second inclined surface inclined in a direction opposite to a direction of the first inclined surface, and the first inclined surface of the non-conductive layer and the second inclined surface of the semiconductor layer are engaged.

15. The semiconductor device according to claim 1, wherein at least a part of the side surface of the semiconductor layer is in close contact with the non-conductive layer.

16. The semiconductor device according to claim 1, wherein at least a part of the side surface of the semiconductor layer is in close contact with the non-conductive layer via a protective film.

17. The semiconductor device according to claim 1, wherein the non-conductive layer is an insulating layer.

18. The semiconductor device according to claim 17, wherein the insulating layer is made of at least one selected from silicon dioxide (Si02) and silicon nitride (Si₃N₄).

19. A semiconductor system comprising at least: a semiconductor device, wherein the semiconductor device is the semiconductor device according to claim 1.
